(19) United States
(12) Patent Application Publication
(10) Pub. No.: US 2025/0189702 A1
(43) Pub. Date: Jun. 12, 2025

(54) OPTICAL FILM AND ORGANIC ELECTROLUMINESCENT DISPLAY DEVICE

(71) Applicant: FUJIFILM Corporation, Tokyo (JP)

(72) Inventors: Toshihiro KONISHI, Minamiashigara-shi (JP); Ayako MURAMATSU, Minamiashigara-shi (JP); Mika AKINO, Minamiashigara-shi (JP)

(73) Assignee: FUJIFILM Corporation, Tokyo (JP)

(21) Appl. No.: 19/053,843

(22) Filed: Feb. 14, 2025

Related U.S. Application Data
(63) Continuation of application No. PCT/JP2023/031677, filed on Aug. 31, 2023.

(30) Foreign Application Priority Data
Sep. 21, 2022 (JP) 2022-150228
Jul. 10, 2023 (JP) 2023-113158

(51) Int. Cl. G02B 5/02; H10K 59/38; H10K 59/80

(52) U.S. Cl. CPC G02B 5/0242; G02B 5/0294; H10K 59/876; H10K 59/38; H10K 59/8793

(57) ABSTRACT

The present invention provides an optical film which is applied to an organic EL display element having a microcavity structure, and in a case where an organic EL display device obtained from to be obtained is viewed from a front direction and an oblique direction, a difference between tint in the front direction and tint in the oblique direction is small; and an organic EL display device. In the optical film of the present invention, a wavelength λmax obtained by a predetermined method X is larger than a wavelength λmin obtained by the predetermined method X, and a scattering rate max obtained by the predetermined method X is 10% to 90%.

### CROSS-REFERENCE TO RELATED APPLICATIONS

This application is a Continuation of PCT International Application No. PCT/JP2023/031677 filed on Aug. 31, 2023, which claims priority under 35 U.S.C. § 119(a) to Japanese Patent Application No. 2022-150228 filed on Sep. 21, 2022 and Japanese Patent Application No. 2023-113158 filed on Jul. 10, 2023. The above applications are hereby expressly incorporated by reference, in their entirety, into the present application.

### BACKGROUND OF THE INVENTION

### 1. Field of the Invention

The present invention relates to an optical film and an organic electroluminescent display device.

### 2. Description of the Related Art

In recent years, self-luminous display elements typified by an organic electroluminescent (hereinafter, also simply referred to as “EL”) display element have attracted attention as a display element constituting a flat display device.

Among these, as disclosed in JP2003-109775A, an organic EL display element having a microcavity structure has excellent brightness and color purity. The microcavity structure is a structure in which an optical path length between upper and lower electrodes (that is, an anode electrode and a cathode electrode) of an organic material is matched to a peak wavelength of a spectrum of light to be extracted, whereby only light having a predetermined wavelength is resonated and light having other wavelengths is weakened.

### SUMMARY OF THE INVENTION

In general, in the organic EL display element, it is desirable that color does not change in a case of being viewed from a normal direction with respect to a light emitting surface (hereinafter, also referred to as “front direction”) and in a case of being viewed from a direction oblique to the light emitting surface (that is, a direction tilted at a predetermined angle from the normal direction; hereinafter, also referred to as “oblique direction”). However, in the organic EL display element having the microcavity structure, the above-described problem is remarkably exhibited.

An object of the present invention is to provide an optical film which is applied to an organic EL display element having a microcavity structure, and in a case where an organic EL display device obtained from to be obtained is viewed from a front direction and an oblique direction, a difference between tint in the front direction and tint in the oblique direction is small.

Another object of the present invention is to provide an organic EL display device.

As a result of intensive studies on the problems in the related art, the present inventors have found that the above-described objects can be accomplished by the following configurations.
(1) An optical film in which a wavelength λmax obtained by a method X described later is larger than a wavelength λmin obtained by the method X, and a scattering rate max obtained by the method X is 10% to 90%.
(2) The optical film according to (1), in which the scattering rate max is 40% to 90%.
(3) The optical film according to (1) or (2),
in which an average value of scattering rates at respective wavelengths calculated using, as the incidence ray, light at each wavelength in a wavelength range of 580 to 700 nm for each 10 nm is 1.5 times or more an average value of scattering rates at respective wavelengths calculated using, as the incidence ray, light at each wavelength in a wavelength range of 400 to 580 nm for each 10 nm.
(4) The optical film according to any one of (1) to (3),
in which the optical film has a region A and a region B having refractive indices different from each other at any wavelength in the wavelength range of 400 to 700 nm,
a difference in refractive index between the region A and the region B is 0.05 or more at any of respective wavelengths in the wavelength range of 400 to 700 nm for each 10 nm, and
the difference in refractive index between the region A and the region B is 0.02 or less at any of respective wavelengths in the wavelength range of 400 to 700 nm for each 10 nm.
(5) The optical film according to (4),
in which, in a case where, among respective wavelengths in the wavelength range of 400 to 700 nm for each 10 nm, a wavelength at which the difference in refractive index between the region A and the region B is maximum is defined as a wavelength λ1, and a wavelength at which the difference in refractive index between the region A and the region B is minimum is defined as a wavelength λ2, the wavelength λ1 is longer than the wavelength λ2.
(6) The optical film according to (4) or (5),
in which the difference in refractive index between the region A and the region B is 0.05 or more at any of respective wavelengths in a wavelength range of 580 to 700 nm for each 10 nm, and
the difference in refractive index between the region A and the region B is 0.02 or less at any of respective wavelengths in a wavelength range of 400 to 580 nm for each 10 nm.
(7) The optical film according to any one of (4) to (6),
in which the region A contains a coloring agent.
(8) The optical film according to (7),
in which a maximal absorption wavelength of the coloring agent is located at 700 nm or more.
(9) The optical film according to (7) or (8),
in which the region A contains the coloring agent and a polymer, and
the region B is composed of particles.
(10) The optical film according to (9),
in which an average particle diameter of the particles is 5.0 μm or less.
(11) The optical film according to any one of (1) to (3),
in which the optical film has a region A and a region B having refractive indices different from each other at any wavelength in the wavelength range of 400 to 700 nm,
the region C contains a polymer, and
the region D is composed of a pigment.
(12) The optical film according to (11),
in which the scattering rate max is 10% to 50%.
(13) The optical film according to (12),
in which the optical film further has a region E which is a region having a refractive index different from the refractive indices of the region C and the region D, and
the region E is composed of particles having an average particle diameter of 4.0 to 9.0 μm.
(14) The optical film according to any one of (11) to (13),
in which an average particle diameter of the pigment is 0.3 to 5.0 km.
(15) The optical film according to any one of (11) to (14),
in which a maximal absorption wavelength of the pigment is 700 nm or more.
(16) The optical film according to any one of (11) to (15),
in which a content of the pigment is 5% to 50% by mass with respect to a total mass of the optical film.
(17) The optical film according to any one of (1) to (3),
in which the optical film has a region F and a region G having refractive indices different from each other at any wavelength in the wavelength range of 400 to 700 nm,
the region F contains a polymer, and
the region G is composed of particles having an average particle diameter of 4.0 to 9.0 μm.
(18) The optical film according to (17),
in which the particles are polymer particles, and
in any wavelength in the wavelength range of 400 to 700 nm, a difference between a refractive index of a polymer contained in the polymer particles and a refractive index of the polymer contained in the region F is 0.1 or more.
(19) The optical film according to any one of (1) to (18),
in which the optical film is applied to an organic electroluminescent display element having a microcavity structure.
(20) An organic electroluminescent display device comprising:
an organic electroluminescent display element having a microcavity structure; and the optical film according to any one of (1) to (19).
(21) The organic electroluminescent display device according to (20), further comprising:
a circularly polarizing plate on a viewing side of the optical film.
(22) The organic electroluminescent display device according to (20) or (21), further comprising:
a color filter on a viewing side of the optical film.
(23) The organic electroluminescent display device according to any one of (20) to (22), further comprising:
an adhesive layer between the organic electroluminescent display element and the optical film.
(24) The organic electroluminescent display device according to (23),
in which an average refractive index of the adhesive layer at a wavelength of 400 to 700 nm is 1.5 to 1.6.
(25) The organic electroluminescent display device according to any one of (20) to (24),
in which the organic electroluminescent display element has a blue light emitting portion, a green light emitting portion, and a red light emitting portion.

According to the present invention, it is possible to provide an optical film which is applied to an organic EL display element having a microcavity structure, and in a case where an organic EL display device obtained from to be obtained is viewed from a front direction and an oblique direction, a difference between tint in the front direction and tint in the oblique direction is small.

In addition, according to the present invention, it is also possible to provide an organic EL display device.

### BRIEF DESCRIPTION OF THE DRAWINGS

FIG. 1 is a diagram showing a scattering rate calculated by a method X.

FIG. 2 is a diagram showing characteristics of an optical film having a region A and a region B.

FIG. 3 is a diagram showing wavelength dispersion characteristics with respect to a refractive index and an absorption coefficient of an organic molecule.

FIG. 4 is a diagram showing another aspect of the optical having a region A and a region B.

FIG. 5 is a diagram showing characteristics of an optical film having a region C and a region D.

FIG. 6 is a diagram for describing characteristics of an optical film having a region F and a region G.

FIG. 7 is a diagram showing an example of an organic EL display device.

### DESCRIPTION OF THE PREFERRED EMBODIMENTS

Hereinafter, the present invention will be described in detail.

Any numerical range expressed using “to” in the present specification refers to a range including the numerical values before and after the “to” as a lower limit value and an upper limit value, respectively.

In addition, an in-plane slow axis and an in-plane fast axis are defined at a wavelength of 550 nm unless otherwise specified. That is, unless otherwise specified, for example, an in-plane slow axis direction means a direction of the in-plane slow axis at a wavelength of 550 nm.

In the present invention, Re(λ) and Rth(λ) represent an in-plane retardation at a wavelength λ and a thickness direction retardation at a wavelength λ, respectively. Unless otherwise specified, the wavelength λ is 550 nm.

In the present invention, Re(λ) and Rth(λ) are values measured at the wavelength of λ in AxoScan (manufactured by Axometrics, Inc.). By inputting an average refractive index ((nx+ny+nz)/3) and a film thickness (d (μm)) in AxoScan,
Slow axis direction (°),

$$Re ( λ ) = R 0 ( λ ) , and \\ Rth ( λ ) = ( ( nx + ny ) / 2 - nz ) \times d$$

are calculated.

Although R0 (λ) is displayed as a numerical value calculated by AxoScan, it means Re (λ).

In the present specification, the refractive indices nx, ny, and nz are measured using an Abbe refractometer (NAR-4T, manufactured by Atago Co., Ltd.) and using a sodium lamp (K=589 nm) as a light source. In addition, in a case of measuring wavelength dependence, it can be measured with a multi-wavelength Abbe refractometer DR-M2 (manufactured by Atago Co., Ltd.) in combination with a dichroic filter.

In addition, values in Polymer Handbook (John Wiley & Sons, Inc.) and catalogs of various optical films can be used. The values of the average refractive index of main optical films are exemplified below: cellulose acylate (1.48), cycloolefin polymer (1.52), polycarbonate (1.59), polymethylmethacrylate (1.49), and polystyrene (1.59).

In the present specification, “visible rays” are intended to mean light at a wavelength of 400 nm or more and less than 700 nm. In addition, “infrared rays” are intended to mean light at a wavelength of 700 nm or more, “near-infrared rays” are intended to mean light at a wavelength from 700 nm to 2,000 nm, and “ultraviolet rays” are intended to mean light at a wavelength of 10 nm or more and less than 400 nm.

In addition, in the present specification, blue light means light having a wavelength of 400 to 500 nm, green light means light having a wavelength of more than 500 nm to 600 nm, and red light means light having a wavelength of more than 600 nm to 700 nm.

In addition, in the present specification, “orthogonal” or “parallel” is intended to include a range of errors acceptable in the art to which the present invention pertains. For example, it means that an angle is in an error range of ±5° with respect to the exact angle, and the error with respect to the exact angle is preferably in a range of ±3°.

A feature point of the optical film according to the embodiment of the present invention is that a wavelength λmax obtained by a method X described later is larger than a wavelength λmin, and a scattering rate max is in a predetermined range.

In the method X described later, a wavelength which is most easily scattered among wavelengths in a wavelength range of 400 to 700 nm for each 10 nm, in a case where light is incident on the optical film is calculated. The fact that the wavelength λmax is larger than the wavelength λmin means that light which is more likely to be scattered is positioned on the long wavelength side. In a case where an organic EL display element having a microcavity structure is viewed from an oblique direction, light having a wavelength on a longer wavelength side (for example, red light) is more difficult to be viewed than in a case where the organic EL display element is viewed from the front direction. Therefore, in a case where the optical film in which the wavelength λmax obtained by the method X is larger than the wavelength λmin and the scattering rate max is in a predetermined range is disposed on the organic EL display element, light having a wavelength on a long wavelength side, which is emitted from the organic EL display element, is easily scattered by the optical film, and as a result, the light having a wavelength on a long wavelength side in an oblique direction increases, and a difference in tint with the front direction is reduced.

### <Optical Film>

In the optical film according to the embodiment of the present invention, a wavelength λmax obtained by the following method X is larger than a wavelength λmin obtained by the following method X, and a scattering rate max obtained by the following method X is 10% to 90%.

Method X: when an incidence ray is incident into the optical film from a normal direction of one surface of the optical film, and a transmittance of light transmitted through the optical film at an angle range of −15° to 15° with respect to a normal direction of the other surface of the optical film is measured for each 1°,
in a case where an integrated value of transmittances in the angle range of −15° to 15° for each 1° is defined as an integrated value A, an integrated value of transmittances in an angle range of −1° to 1° for each 1° is defined as an integrated value B, and a proportion of an absolute value of a difference between the integrated value A and the integrated value B with respect to the integrated value A is defined as a scattering rate,
among scattering rates at respective wavelengths calculated using, as the incidence ray, light at each wavelength in a wavelength range of 400 to 700 nm for each 10 nm, the highest scattering rate is defined as the scattering rate max, a wavelength of the incidence ray at which the scattering rate max is exhibited is defined as the wavelength λmax, and a wavelength of the incidence ray at which the lowest scattering rate is exhibited is defined as the wavelength λmin.

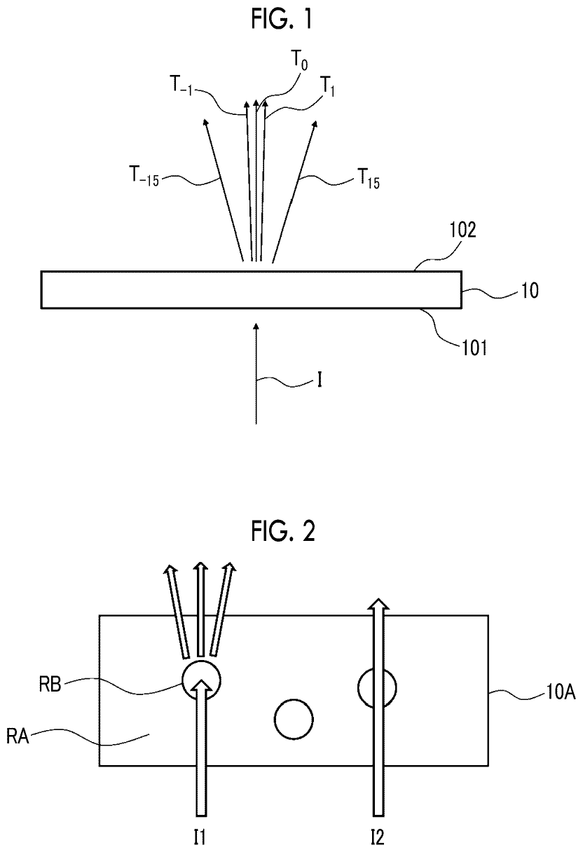

Hereinafter, the method X will be described in more detail with reference to FIG. 1.

In the method X, first, as shown in FIG. 1, an incidence ray I is incident from a normal direction of one surface 101 of an optical film 10.

As will be described later, light having each wavelength in a wavelength range of 400 to 700 nm for each 10 nm is used as the incidence ray I. More specifically, light of each wavelength (400+10×m (m represents an integer of 0 to 30)) (nm) obtained by adding 10 nm from a wavelength of 400 nm is used as the incidence ray. That is, the wavelength of the incidence ray is light having a wavelength of every 10 nm of 400 nm, 410 nm, 420 nm, . . . , 680 nm, 690 nm, and 700 nm.

Next, a transmittance of light (transmitted light) transmitted through the optical film 10 is measured in an angle range of −15° to 15° with respect to a normal direction of the other surface 102 of the optical film 10 for each 1°. That is, a transmittance of the transmitted light is measured in directions at intervals of 1° within an angle range of −15° to 15°. In FIG. 1, typically, a transmitted light T₁₅ in an angle direction of 15° with respect to the normal direction of the surface 102, a transmitted light T₁ in an angle direction of 1° with respect to the normal direction of the surface 102, a transmitted light T₀ in an angle direction of 0° with respect to the normal direction of the surface 102, a transmitted light T₋₁ in an angle direction of −1° with respect to the normal direction of the surface 102, and a transmitted light T₋₁₅ in an angle direction of −15° with respect to the normal direction of the surface 102 are shown; but the transmittance of the transmitted light in directions of −15° to 150 is measured for each 10 (−15°, −14°, −13°, −12°, −11°, −10°, −9°, 8°, −7°, −6°, −5°, −4°, −3°, −2°, −1, 0°, 1, 2°, 3°, 4°, 5°, 6°, 7°, 8°, 9°, 10°, 11°, 12°, 13°, 14°, and 15°).

Next, an integrated value A which is an integrated value of the transmittances in the angle range of −15° to 150 for each 10 with respect to the normal direction of the surface 102 is obtained. That is, the transmittance of each transmitted light in an angle direction of every 1° from −15° to 150 with respect to the normal direction of the surface 102 is added up, and the obtained total value (integrated value) is defined as the integrated value A.

Next, an integrated value B which is an integrated value of the transmittances in the angle range of −1° to 1° for each 1° with respect to the normal direction of the surface 102 is obtained. That is, the transmittance of the transmitted light T₋₁ in an angle direction of −1° with respect to the normal direction of the surface 102, the transmittance of the transmitted light T₀ in an angle direction of 0° with respect to the normal direction of the surface 102, and the transmittance of the transmitted light T₁ in an angle direction of 1° with respect to the normal direction of the surface 102 are added up, and the obtained total value (integrated value) is defined as the integrated value B.

The integrated value B represents the amount of light transmitted without being scattered much. Therefore, as the absolute value of the difference between the integrated value A and the integrated value B is larger, the degree of scattering of the transmitted light is larger. Therefore, a proportion of the absolute value of the difference between the integrated value A and the integrated value B to the integrated value A is defined as the scattering rate.

In the method X, the scattering rate at each wavelength calculated using, as the incidence ray, light at each wavelength in a wavelength range of 400 to 700 nm for each 10 nm is calculated by the above-described method. For example, light having a wavelength of 600 nm is incident, the integrated value A and the integrated value B are calculated, and the scattering rate at the wavelength of 600 nm is obtained.

Next, among obtained scattering rates at respective wavelengths, the highest scattering rate is defined as the scattering rate max, and a wavelength of incidence ray at which the scattering rate max is exhibited is defined as the wavelength λmax.

On the other hand, among obtained scattering rates at respective wavelengths, a wavelength of incidence ray at which the scattering rate is the lowest scattering rate is exhibited is defined as the wavelength λmin.

For example, in a case where a scattering rate obtained in a case where light having a wavelength of 650 nm is used as the incidence ray is larger than a scattering rate of incidence ray having another wavelength, the wavelength of 650 nm is the wavelength λmax. In addition, in a case where a scattering rate obtained in a case where light having a wavelength of 450 nm is used as the incidence ray is smaller than a scattering rate of incidence ray having another wavelength, the wavelength of 450 nm is the wavelength λmin.

In the optical film according to the embodiment of the present invention, the wavelength λmax obtained by the above-described method X is larger than the wavelength λmin. As described above, the optical film satisfying the characteristics means that light on the longer wavelength side is likely to be scattered.

From the viewpoint that, in a case where the optical film according to the embodiment of the present invention is applied to an organic EL display element having a microcavity structure and the obtained organic EL display device is viewed from a front direction and an oblique direction, a difference between a tint in the front direction and a tint in the oblique direction is smaller (hereinafter, also simply referred to as “effect of the present invention is more excellent”), the wavelength λmax is preferably in a range of 580 to 700 nm, more preferably in a range of 600 to 700 nm, and still more preferably in a range of 610 to 700 nm.

From the viewpoint that the effect of the present invention is more excellent, the wavelength λmin is preferably in a range of 400 to 580 nm and more preferably in a range of 400 to 570 nm.

In the optical film according to the embodiment of the present invention, the scattering rate max is 10% to 90%. Among these, from the viewpoint that the effect of the present invention is more excellent, the scattering rate max is preferably 40% to 90%, more preferably 55% to 90%, and still more preferably 60% to 90%.

The wavelength λmax, the wavelength λmin, and the scattering rate max described above can be measured using a commercially available goniophotometer (GCMS-3B).

Among these, in the optical film according to the embodiment of the present invention, from the viewpoint that the effect of the present invention is more excellent, it is preferable that an average value of the above-described scattering rates at respective wavelengths calculated using, as the incidence ray, light at each wavelength in a wavelength range of 580 to 700 nm for each 10 nm (hereinafter, also simply referred to as “average value 1”) is 1.5 times or more an average value of the above-described scattering rates at respective wavelengths calculated using, as the incidence ray, light at each wavelength in a wavelength range of 400 to 580 nm for each 10 nm (hereinafter, also referred to as “average value 2”). That is, a ratio of the average value 1 to the average value 2 is preferably 1.5 or more.

The ratio of the average value 1 to the average value 2 is more preferably 1.8 or more, and still more preferably 2.0 or more. The upper limit thereof is not particularly limited, but is preferably 8.0 or less, and more preferably 5.0 or less.

The above-described average value 1 is an arithmetic mean value of the above-described scattering rates at respective wavelengths calculated using, as the incidence ray, light at each wavelength in a wavelength range of 580 to 700 nm for each 10 nm.

The above-described average value 2 is an arithmetic mean value of the above-described scattering rates at respective wavelengths calculated using, as the incidence ray, light at each wavelength in a wavelength range of 400 to 580 nm for each 10 nm.

Examples of one suitable aspect of the optical film according to the embodiment of the present invention include an aspect in which the optical film has a region A and a region B having refractive indices different from each other at any wavelength in a wavelength range of 400 to 700 nm, a difference in refractive index between the region A and the region B is 0.05 or more at any of respective wavelengths in the wavelength range of 400 to 700 nm for each 10 nm, and the difference in refractive index between the region A and the region B is 0.02 or less at any of respective wavelengths in the wavelength range of 400 to 700 nm for each 10 nm.

Characteristics of the optical film satisfying the above-described configuration will be described with reference to FIG. 2.

An optical film 10A shown in FIG. 2 has a region A (RA) and a region B (RB) having refractive indices different from each other at any wavelength λt any wavelength in a wavelength range of 400 to 700 nm.

In FIG. 2, a sea-island structure in which the region B (RB) is present in an island shape in the region A (RA) is formed. As will be described later, for example, since materials constituting the region A and the region B are different from each other, a state in which the refractive indices are different from each other at a specific wavelength can be achieved.

It is preferable that the difference in refractive index between the region A and the region B is 0.05 or more at any of respective wavelengths in the wavelength range of 400 to 700 nm for each 10 nm. In a case where light having a wavelength at which the difference in refractive index between the region A and the region B is 0.05 or more is incident on the optical film, the incidence ray is likely to be scattered in the optical film. More specifically, in a case where the difference in refractive index between the region A and the region B at a wavelength of an incidence ray I1 shown in FIG. 2 is 0.05 or more, the incidence ray I1 is likely to be scattered because refraction or the like is likely to occur at an interface between the region A and the region B.

In a case where the above-described difference in refractive index between the region A and the region B is 0.05 or more, the difference in refractive index between the region A and the region B is preferably 0.07 or more, and more preferably 0.10 or more. The upper limit thereof is not particularly limited, but is preferably 0.20 or less, and more preferably 0.15 or less.

In addition, it is preferable that the difference in refractive index between the region A and the region B is 0.02 or less at any of respective wavelengths in the wavelength range of 400 to 700 nm for each 10 nm. In a case where light having a wavelength at which the difference in refractive index between the region A and the region B is 0.02 or less is incident on the optical film, the light can be transmitted without being scattered. More specifically, in a case where the difference in refractive index between the region A and the region B at a wavelength of an incidence ray I2 shown in FIG. 2 is 0.02 or less, the incidence ray I2 can be transmitted without being scattered because refraction or the like is less likely to occur at the interface between the region A and the region B.

In a case where the above-described difference in refractive index between the region A and the region B is 0.02 or less, the difference in refractive index between the region A and the region B is preferably 0.015 or less, and more preferably 0.01 or less. The lower limit thereof is not particularly limited, but may be, for example, 0.

When there is a wavelength at which the difference in refractive index between the region A and the region B is 0.05 or more, in a case where light having the wavelength is incident on the optical film, transmitted light is likely to be scattered, and as a result, the wavelength (wavelength at which the difference in refractive index between the region A and the region B is 0.05 or more) is likely to correspond to the above-described wavelength λmax.

In addition, when there is a wavelength at which the difference in refractive index between the region A and the region B is 0.02 or less, in a case where light having the wavelength is incident on the optical film, the light is likely to be transmitted without being scattered, and as a result, the wavelength (wavelength at which the difference in refractive index between the region A and the region B is 0.02 or less) is likely to correspond to the above-described wavelength λmin.

That is, in a case where the optical film has the above-described suitable aspect, it is possible to cause the scattering of the light having the wavelength λmax while preventing the scattering of the light having the wavelength λmin.

In addition, in the above-described suitable aspect, from the viewpoint that the effect of the present invention is more excellent, it is preferable that, in a case where, among respective wavelengths in the wavelength range of 400 to 700 nm for each 10 nm, a wavelength at which the difference in refractive index between the region A and the region B is maximum is defined as a wavelength λ1, and a wavelength at which the difference in refractive index between the region A and the region B is minimum is defined as a wavelength λ2, the wavelength λ1 is longer than the wavelength λ2.

In a case where the optical film satisfies the above-described requirement (wavelength λ1 is longer than the wavelength λ2), the wavelength λ1 is likely to correspond to the above-described wavelength λmax and the wavelength λ2 is likely to correspond to the above-described wavelength λmin.

A suitable range of the wavelength λ1 is same as the above-described suitable range of the wavelength λmax.

A suitable range of the wavelength λ2 is same as the above-described suitable range of the wavelength λmin.

In addition, in the above-described suitable aspect, from the viewpoint that the effect of the present invention is more excellent, it is preferable that the difference in refractive index between the region A and the region B is 0.05 or more at any of respective wavelengths in a wavelength range of 580 to 700 nm for each 10 nm, and the difference in refractive index between the region A and the region B is 0.02 or less at any of respective wavelengths in a wavelength range of 400 to 580 nm for each 10 nm.

In particular, it is preferable that the difference in refractive index between the region A and the region B is 0.05 or more at any of respective wavelengths at a wavelength 600 to 650 nm for each 10 nm, and the difference in refractive index between the region A and the region B is 0.02 or less at any of respective wavelengths in a wavelength range of 400 to 570 nm for each 10 nm.

In order to obtain the above-described optical film having the region A and the region B shown in FIG. 2, a method of incorporating a coloring agent into the optical film may be used.

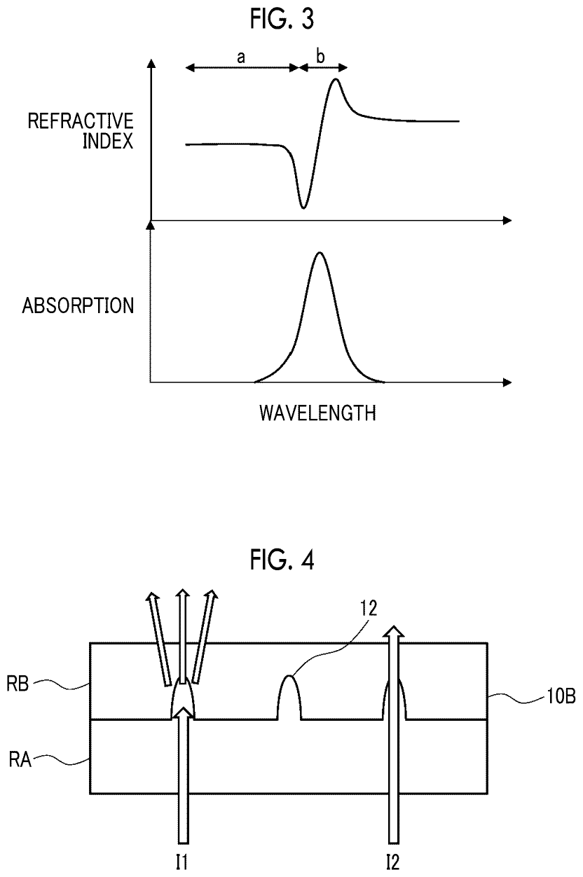

In the following, first, refractive index wavelength dispersion characteristics of a general organic molecule will be described with reference to FIG. 3. In FIG. 3, the upper side shows a behavior of a refractive index with respect to a wavelength, and the lower side shows a behavior (absorption spectrum) of absorption characteristics with respect to the wavelength.

For the organic molecule, a refractive index n in a region (region a in FIG. 3) away from an intrinsic absorption wavelength decreases monotonically as the wavelength increases. Such a dispersion is referred to as “normal dispersion”. In contrast, a refractive index n in a wavelength band including an intrinsic absorption (region b in FIG. 3) rapidly increases as the wavelength increases. Such a dispersion is referred to as “anomalous dispersion”.

That is, as shown in FIG. 3, an increase or a decrease in the refractive index is observed immediately before the wavelength range having absorption.

Therefore, in order to obtain the above-described optical film, for example, an infrared absorbing coloring agent is contained in the region A (RA) of the optical film 10A shown in FIG. 2. More specifically, in a case where an infrared absorbing coloring agent having a maximal absorption wavelength of 700 nm or more (preferably, approximately 700 to 1200 nm) is contained in the region A (RA), the refractive index of the region A in a range on the long wavelength side in the visible light region (for example, a wavelength range of 580 to 700 nm) is smaller than the refractive index in other wavelength ranges, for example, under the influence of the characteristics of the “normal dispersion” in which the refractive index rapidly decreases in a wavelength range before the maximal absorption wavelength λs shown in FIG. 3. That is, in the region A, the refractive index in the range on the long wavelength side (for example, the wavelength range of 580 to 700 nm) can be smaller than the refractive index in the range on the short wavelength side (for example, a wavelength range of 400 to 580 nm). Such an optical film easily achieves the above-described relationship between the wavelength λmax and the wavelength λmin, and the above-described relationship between the wavelength λ1 and the wavelength λ2. More specifically, in a case where the region A contains the above-described predetermined near-infrared absorbing coloring agent, the difference in refractive index between the region A and the region B at each wavelength in a range on the short wavelength side (for example, a wavelength range of 400 to 580 nm) is small, but the difference in refractive index between the region A and the region B at each wavelength in a range on the long wavelength side (for example, a wavelength range of 580 to 700 nm) is large. Therefore, it is easy to obtain the optical film satisfying the above-described predetermined characteristics.

In the above description, the aspect in which the near-infrared absorbing coloring agent is contained in the region A present in the sea shape has been described, but the near-infrared absorbing coloring agent may be contained in the region B present in the island shape.

In addition, in the above description, the aspect in which the near-infrared absorbing coloring agent is used has been described, but a coloring agent exhibiting other absorption characteristics may be used. For example, in a case where a visible light absorbing coloring agent exhibiting a maximal absorption wavelength λt a wavelength of 500 nm is used instead of the above-described near-infrared absorbing coloring agent in the region A present in the sea shape, a decrease in refractive index occurs in a short wavelength range with respect to a wavelength of 500 nm (for example, a range of 450 nm±20 nm), and an increase in refractive index occurs in a long wavelength range of the wavelength of 500 nm (for example, a range of 550 nm±20 nm). In this case, the difference in refractive index between the region A and the region B is substantially zero at the wavelength of 500 nm, but the difference in refractive index between the region A and the region B occurs in the short wavelength range with respect to the wavelength of 500 nm (for example, a range of 450 nm±20 nm) and in the long wavelength range of the wavelength of 500 nm (for example, a range of 550 nm±20 nm); and in a case where light in these wavelength ranges is incident on the optical film, the light is likely to be scattered. Therefore, the coloring agent to be used can be appropriately selected depending on a wavelength of light to be scattered according to the performance of the organic EL display element to which the optical film according to the embodiment of the present invention is applied.

In FIG. 2, the aspect in which the region B is dispersed in the region A in the island shape has been described, but the distribution state of the region A and the region B included in the optical film may be in another aspect as long as the interface between the region A and the region B is present and the scattering can occur.

For example, FIG. 4 is a cross-sectional view of another aspect of the optical film in which the distribution state of the region A and the region B is different from above. An optical film 10B has a layered region A (RA) and a layered region B (RB), and the region A has a protruding portion 12 which protrudes to the region B side.

In a case where a difference in refractive index between the region A (RA) and the region B (RB) at a wavelength of an incidence ray I1 shown in FIG. 4 is 0.05 or more, the incidence ray I1 is likely to be scattered because refraction or the like is likely to occur at an interface between the region A (RA) and the region B (RB).

In addition, in a case where the difference in refractive index between the region A (RA) and the region B (RB) at a wavelength of an incidence ray I2 shown in FIG. 4 is 0.02 or less, the incidence ray I2 can be transmitted without being scattered because refraction or the like is less likely to occur at the interface between the region A (RA) and the region B (RB).

Examples of one suitable aspect of the optical film according to the embodiment of the present invention include an aspect in which the optical film has a region A and a region B having refractive indices different from each other at any wavelength in the wavelength range of 400 to 700 nm, the region C contains a polymer, and the region D is composed of a pigment.

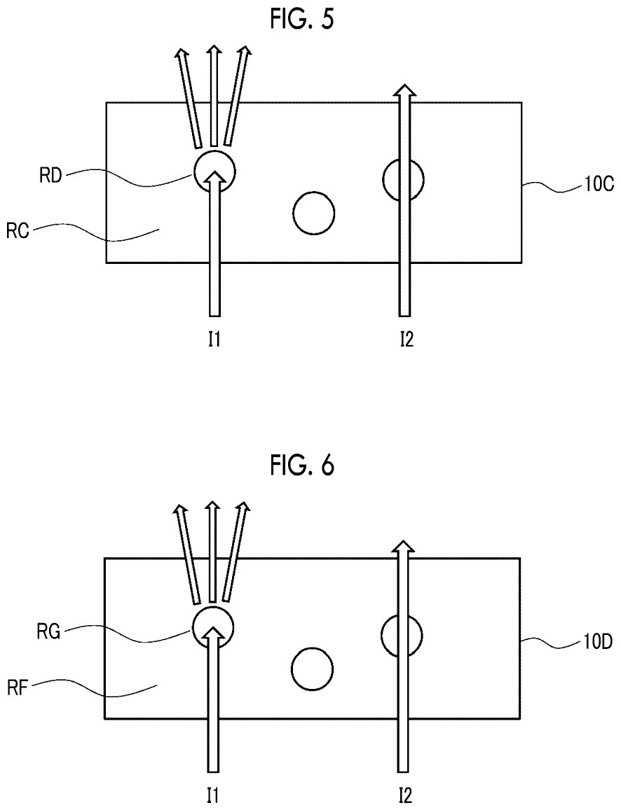

Characteristics of the optical film satisfying the above-described configuration will be described with reference to FIG. 5.

An optical film 10C shown in FIG. 5 has a region C (RC) and a region D (RD) having refractive indices different from each other at any wavelength λt any wavelength in a wavelength range of 400 to 700 nm.

In FIG. 5, a sea-island structure in which the region D (RD) is present in an island shape in the region C (RC) is formed. As will be described later, for example, since materials constituting the region C and the region D are different from each other, a state in which the refractive indices are different from each other at a specific wavelength can be achieved.

It is preferable that the difference in refractive index between the region C and the region D is 0.05 or more at any of respective wavelengths in the wavelength range of 400 to 700 nm for each 10 nm. In a case where light having a wavelength at which the difference in refractive index between the region C and the region D is 0.05 or more is incident on the optical film, the incidence ray is likely to be scattered in the optical film. More specifically, in a case where the difference in refractive index between the region C and the region D at a wavelength of an incidence ray I1 shown in FIG. 5 is 0.05 or more, the incidence ray I1 is likely to be scattered because refraction or the like is likely to occur at an interface between the region C and the region D.

In a case where the above-described difference in refractive index between the region C and the region D is 0.05 or more, the difference in refractive index between the region C and the region D is preferably 0.07 or more, and more preferably 0.10 or more. The upper limit thereof is not particularly limited, but is preferably 1.5 or less, and more preferably 1.0 or less.

On the other hand, it is preferable that the difference in refractive index between the region C and the region D is 0.02 or less at any of respective wavelengths in the wavelength range of 400 to 700 nm for each 10 nm. In a case where light having a wavelength at which the difference in refractive index between the region C and the region D is 0.02 or less is incident on the optical film, the light can be transmitted without being scattered. More specifically, in a case where the difference in refractive index between the region C and the region D at a wavelength of an incidence ray I2 shown in FIG. 5 is 0.02 or less, the incidence ray I2 can be transmitted without being scattered because refraction or the like is less likely to occur at the interface between the region C and the region D.

In a case where the above-described difference in refractive index between the region C and the region D is 0.02 or less, the difference in refractive index between the region C and the region D is preferably 0.015 or less, and more preferably 0.01 or less. The lower limit thereof is not particularly limited, but may be, for example, 0.

When there is a wavelength at which the difference in refractive index between the region C and the region D is 0.05 or more, in a case where light having the wavelength is incident on the optical film, transmitted light is likely to be scattered, and as a result, the wavelength (wavelength at which the difference in refractive index between the region C and the region D is 0.05 or more) is likely to correspond to the above-described wavelength λmax.

In addition, when there is a wavelength at which the difference in refractive index between the region C and the region D is 0.02 or less, in a case where light having the wavelength is incident on the optical film, the light is likely to be transmitted without being scattered, and as a result, the wavelength (wavelength at which the difference in refractive index between the region C and the region D is 0.02 or less) is likely to correspond to the above-described wavelength λmin.

That is, in a case where the optical film has the above-described suitable aspect, it is possible to cause the scattering of the light having the wavelength λmax while preventing the scattering of the light having the wavelength λmin.

In addition, in the above-described suitable aspect, from the viewpoint that the effect of the present invention is more excellent, it is preferable that, in a case where, among respective wavelengths in the wavelength range of 400 to 700 nm for each 10 nm, a wavelength at which the difference in refractive index between the region C and the region D is maximum is defined as a wavelength λ1, and a wavelength at which the difference in refractive index between the region C and the region D is minimum is defined as a wavelength λ2, the wavelength λ1 is longer than the wavelength λ2.

In a case where the optical film satisfies the above-described requirement (wavelength λ1 is longer than the wavelength λ2), the wavelength λ1 is likely to correspond to the above-described wavelength λmax and the wavelength λ2 is likely to correspond to the above-described wavelength λmin.

A suitable range of the wavelength λ1 is same as the above-described suitable range of the wavelength λmax.

A suitable range of the wavelength λ2 is same as the above-described suitable range of the wavelength λmin.

In addition, in the above-described suitable aspect, from the viewpoint that the effect of the present invention is more excellent, it is preferable that the difference in refractive index between the region C and the region D is 0.05 or more at any of respective wavelengths in a wavelength range of 580 to 700 nm for each 10 nm, and the difference in refractive index between the region C and the region D is 0.02 or less at any of respective wavelengths in a wavelength range of 400 to 580 nm for each 10 nm.

In particular, it is preferable that the difference in refractive index between the region C and the region D is 0.05 or more at any of respective wavelengths at a wavelength 600 to 650 nm for each 10 nm, and the difference in refractive index between the region C and the region D is 0.02 or less at any of respective wavelengths in a wavelength range of 400 to 570 nm for each 10 nm.

In order to obtain the above-described optical film, for example, the region D (RD) of the optical film 10C shown in FIG. 5 is composed of a pigment. More specifically, in a case where the region D (RD) is composed of a pigment having a maximal absorption wavelength of 700 nm or more (preferably, approximately 700 to 1200 nm) is contained in the region A (RA), the refractive index of the region D in a range on the long wavelength side in the visible light region (for example, a wavelength range of 580 to 700 nm) is smaller than the refractive index in other wavelength ranges, for example, under the influence of the characteristics of the “normal dispersion” in which the refractive index rapidly decreases in a wavelength range before the maximal absorption wavelength λs shown in FIG. 3. That is, in the region D, the refractive index in the range on the long wavelength side (for example, the wavelength range of 580 to 700 nm) can be smaller than the refractive index in the range on the short wavelength side (for example, a wavelength range of 400 to 580 nm). Such an optical film easily achieves the above-described relationship between the wavelength λmax and the wavelength λmin, and the above-described relationship between the wavelength λ1 and the wavelength λ2. More specifically, in a case where the region D is composed of the above-described pigment having a predetermined maximal absorption wavelength, the difference in refractive index between the region C and the region D at each wavelength in a range on the short wavelength side (for example, a wavelength range of 400 to 580 nm) is small, but the difference in refractive index between the region C and the region D at each wavelength in a range on the long wavelength side (for example, a wavelength range of 580 to 700 nm) is large. Therefore, it is easy to obtain the optical film satisfying the above-described predetermined characteristics.

In the above-described optical film having the region C and the region D, the scattering rate max is preferably 10% to 50%, more preferably 15% to 50%, still more preferably 20% to 50%, and particularly preferably 20% to 40%.

In addition, the above-described optical film having the region C and the region D may further have a region E which is a region having a refractive index different from the refractive indices of the region C and the region D.

It is preferable that the region E is composed of particles having an average particle diameter of 4.0 to 9.0 μm.

A difference in refractive index between the region E and the region C is not particularly limited, but is preferably 0.1 or more and more preferably 0.12 or more at any of respective wavelengths in the wavelength range of 400 to 700 nm for each 10 nm.

Examples of one suitable aspect of the optical film according to the embodiment of the present invention include an aspect in which the optical film has a region F and a region G having refractive indices different from each other at any wavelength in the wavelength range of 400 to 700 nm, the region F contains a polymer, and the region G is composed of particles having an average particle diameter of 4.0 to 9.0 μm.

Characteristics of the optical film satisfying the above-described configuration will be described with reference to FIG. 6.

An optical film 10D shown in FIG. 6 has a region F (RF) and a region G (RG) having refractive indices different from each other at any wavelength λt any wavelength in a wavelength range of 400 to 700 nm.

In FIG. 6, a sea-island structure in which the region F (RF) is present in an island shape in the region G (RG) is formed.

A difference in refractive index between the region F and the region G is preferably 0.10 or more, and more preferably 0.12 or more at any wavelength of 400 to 700 nm. The upper limit of the above-described difference in refractive index is not particularly limited, but is preferably 0.20 or less.

In addition, the difference in refractive index between the region F and the region G is preferably 0.08 or more, and more preferably 0.10 or more at any wavelength of 400 to 700 nm. The upper limit of the above-described difference in refractive index is not particularly limited, but is preferably 0.20 or less.

In the above-described optical film, since the region G is composed of particles having a predetermined size, the above-described characteristics are exhibited. That is, by using particles having an average particle diameter of 4.0 to 9.0 μm, light having a wavelength in a range on the long wavelength side (for example, a wavelength range of 580 to 700 nm) is likely to be scattered.

A thickness of the optical film is not particularly limited, but from the viewpoint of thinning, it is preferably 40 μm or less, and more preferably 20 μm or less. The lower limit thereof is not particularly limited, but is preferably 1 μm or more.

### (Material of Optical Film)

Hereinafter, materials constituting the optical film will be described in detail.

The material to be used is not particularly limited as long as the optical film exhibits the above-described characteristics.

The optical film preferably contains a polymer. The type of the polymer is not particularly limited, and examples thereof include poly(meth)acrylate, polyester, polystyrene, polycarbonate, polyolefin, and polyurethane.

In addition, as will be described later, in a case where the optical film is formed of a polymerizable composition containing a monomer, a cured product of the monomer may correspond to the above-described polymer.

In a case where the optical film has the above-described region A and region B, it is preferable that the region A contains a coloring agent and a polymer, and the region B is composed of particles (preferably, organic particles).

As shown in FIG. 2, it is preferable that the region A and the region B form a sea-island structure in which the region A is disposed in a sea shape and the region B is disposed in an island shape.

The type of the polymer contained in the region A is not particularly limited, and examples thereof include the materials exemplified as the polymers which may be contained in the optical film described above. In addition, the polymer contained in the region A may be a pressure sensitive adhesive.

A content of the polymer contained in the region A is not particularly limited, but is preferably 50% to 99% by mass, and more preferably 60% to 90% by mass with respect to the total mass of the optical film.

The type of the coloring agent contained in the region A is not particularly limited, and an optimum coloring agent is selected according to the wavelength of the light to be scattered as described above. Among these, an infrared absorbing coloring agent is preferable.

The infrared absorbing coloring agent is a coloring agent having a maximal absorption wavelength in the infrared region.

A molecular weight of the infrared absorbing coloring agent is not particularly limited, but is preferably less than 5,000. The lower limit thereof is not particularly limited, but is usually 500 or more.

Examples of the infrared absorbing coloring agent include a diketopyrrolopyrrole-based coloring agent, a diimmonium-based coloring agent, a phthalocyanine-based coloring agent, a naphthalocyanine-based coloring agent, an azo-based coloring agent, a polymethine-based coloring agent, an anthraquinone-based coloring agent, a pyrylium-based coloring agent, a squarylium-based coloring agent, a triphenylmethane-based coloring agent, a cyanine-based coloring agent, an ammonium-based coloring agent, a croconium-based coloring agent, a perylene-based coloring agent, a metal complex-based coloring agent, an oxonol-based coloring agent, a merocyanine-based coloring agent, and a dithiophenophosphorine-based coloring agent.

The infrared absorbing coloring agent may be used alone or in combination of two or more kinds thereof.

As the infrared absorbing coloring agent, a coloring agent having a maximal absorption wavelength in the near-infrared region (near-infrared absorbing coloring agent) is preferable.

From the viewpoint that the effect of the present invention is more excellent, the maximal absorption wavelength of the infrared absorbing coloring agent is preferably located at a wavelength of 700 nm or more, more preferably located at a wavelength in a range of 700 to 1,200 nm, and still more preferably located at a wavelength in a range of 700 to 900 nm.

As a method of measuring the maximal absorption wavelength of the coloring agent, a chloroform solution containing the coloring agent (concentration: 10 μmg/L) and a reference containing no coloring agent are prepared, and an absorption spectrum of the coloring agent is measured using a spectrophotometer (UV-3150 μmanufactured by Shimadzu Corporation) to obtain the maximal absorption wavelength of the coloring agent.

A content of the coloring agent contained in the region A is not particularly limited, but is preferably 0.5% to 50% by mass and more preferably 2% to 30% by mass with respect to the total mass of the polymer contained in the region A.

The particles constituting the region B may be organic particles or inorganic particles, and are preferably organic particles. In addition, the organic particles preferably contain a polymer. Examples of the type of the polymer include the materials exemplified as the polymers which may be contained in the optical film described above.

A material constituting the inorganic particles is not particularly limited, and examples thereof include a non-metal oxide (for example, silicon dioxide), a metal oxide (for example, aluminum oxide), and a metal nitride.

The polymer contained in the region A and the polymer contained in the organic particles constituting the region B may be the same or different from each other.

An average particle diameter of the particles is not particularly limited, but from the viewpoint that the effect of the present invention is more excellent, it is preferably 5.0 μm or less and more preferably 2.0 μm or less. The lower limit thereof is not particularly limited, but is preferably 0.1 μm or more, and more preferably 0.5 μm or more.

As a method for measuring the average particle diameter of the particles, a cross section of the optical film is observed with a scanning electron microscope, major axes of the particles constituting the observed region B are measured at at least 10 locations, and the obtained values are arithmetically averaged to obtain the average particle diameter of the particles.

A content of the particles contained in the region B is not particularly limited, but is preferably 5% to 40% by mass and more preferably 10% to 30% by mass with respect to the total mass of the optical film.

In a case where the optical film has the above-described region C and region D, as described above, it is preferable that the region C contains a polymer and the region D is composed of a pigment.

As shown in FIG. 5, it is preferable that the region C and the region D form a sea-island structure in which the region C is disposed in a sea shape and the region D is disposed in an island shape.

The type of the polymer contained in the region C is not particularly limited, and examples thereof include the materials exemplified as the polymers which may be contained in the optical film described above.

A content of the polymer contained in the region C is not particularly limited, but is preferably 50% to 95% by mass, and more preferably 60% to 90% by mass with respect to the total mass of the optical film.

The type of the pigment constituting the region D is not particularly limited, and an optimum coloring agent is selected according to the wavelength of the light to be scattered as described above. Among these, a pigment having a maximal absorption wavelength of 700 nm or more is preferable. The maximal absorption wavelength of the pigment is preferably located in a range of 700 to 1,200 nm and more preferably located in a range of 700 to 1,000 nm.

As a method for measuring the maximal absorption wavelength of the pigment, first, a polystyrene film containing the pigment (pigment concentration in the film: 20% by mass) and a polystyrene film containing no pigment as a reference are prepared, and an absorption spectrum of the pigment is measured by comparing the two films using a spectrophotometer (UV-3150 μmanufactured by Shimadzu Corporation) to obtain the maximal absorption wavelength of the pigment.

The type of the pigment is not particularly limited, and examples thereof include a cyanine compound, a phthalocyanine compound, a quinone-based compound, a squarylium compound, a croconium compound, an azo compound, a diimmonium compound, a perylene compound, and a pyrrolo pyrrole compound.

The pigment may be used alone or in combination of two or more thereof.

An average particle diameter of the pigment is not particularly limited, but from the viewpoint that the effect of the present invention is more excellent, it is preferably 0.3 to 5.0 m and more preferably 0.3 to 2.0 μm.

As a method for measuring the average particle diameter of the pigment, a cross section of the optical film is observed with a scanning electron microscope, major axes of the observed pigments are measured at at least 10 locations, and the obtained values are arithmetically averaged to obtain the average particle diameter of the pigment.

A content of the pigment constituting the region D is not particularly limited, but is preferably 5% to 50% by mass and more preferably 10% to 40% by mass with respect to the total mass of the optical film.

In a case where the optical film has the above-described region C and region D, the optical film may have a region E which is a region having a refractive index different from the refractive indices of the region C and the region D.

It is preferable that the region E is composed of particles having an average particle diameter of 4.0 to 9.0 μm.

An average particle diameter of the above-described particles is preferably 4.5 to 8.5 m.

As a method for measuring the average particle diameter of the particles, a cross section of the optical film is observed with a scanning electron microscope, major axes of the particles are measured at at least 10 locations, and the obtained values are arithmetically averaged to obtain the average particle diameter of the particles.

The above-described particles may be organic particles or inorganic particles. Among these, organic particles are preferable, and polymer particles are more preferable.

The type of the polymer contained in the polymer particles is not particularly limited, and examples thereof include the materials exemplified as the polymers which may be contained in the optical film described above.

A content of the particles contained in the region E is not particularly limited, but is preferably 5% to 40% by mass and more preferably 10% to 30% by mass with respect to the total mass of the optical film.

In a case where the optical film has the above-described region F and region G, as described above, it is preferable that the region F contains a polymer and the region G is composed of particles having an average particle diameter of 4.0 to 9.0 μm.

As shown in FIG. 6, it is preferable that the region F and the region G form a sea-island structure in which the region F is disposed in a sea shape and the region G is disposed in an island shape.

The type of the polymer contained in the region F is not particularly limited, and examples thereof include the materials exemplified as the polymers which may be contained in the optical film described above.

A content of the polymer contained in the region F is not particularly limited, but is preferably 50% to 95% by mass, and more preferably 60% to 90% by mass with respect to the total mass of the optical film.

Examples of the particles constituting the region G include the particles having an average particle diameter of 4.0 to 9.0 μm, constituting the region E described above.

A content of the particles contained in the region G is not particularly limited, but is preferably 5% to 40% by mass and more preferably 10% to 30% by mass with respect to the total mass of the optical film.

### (Manufacturing Method of Optical Film)

A manufacturing method of the optical film is not particularly limited, and a known method can be adopted.

Among these, a method of using a polymerizable composition is exemplified from the viewpoint that the optical film is easily manufactured. Examples of components contained in the polymerizable composition include a monomer, a coloring agent, and particles.

The monomer to be used is not particularly limited as long as it is a monomer which can constitute the above-described polymer contained in the region A after polymerization.

In addition, examples of the coloring agent to be used include the above-described coloring agent contained in the region A.

In addition, examples of the particles to be used include the above-described particles constituting the region B.

The polymerizable composition may contain components other than the above-described components.

Examples of other components include a polymerization initiator. The polymerization initiator used is selected according to the type of polymerization reaction, and examples thereof include a thermal polymerization initiator and a photopolymerization initiator.

Examples of the other components include a leveling agent, a plasticizer, and a solvent, in addition to the above-described components.

Examples of a procedure for manufacturing the optical film using the polymerizable composition include a method of applying the polymerizable composition onto a substrate and subjecting the obtained coating film to a curing treatment.

The type of the substrate to be used is not particularly limited, and examples thereof include known substrates.

The substrate may be a so-called temporary support. That is, in a case where the substrate is a temporary support, an optical film with a temporary support, including the temporary support and the optical film, is finally obtained. Since the temporary support can be peeled off, the above-described optical film with a temporary support can be used as a so-called transfer film.

Examples of a method of applying the polymerizable composition include a curtain coating method, a dip coating method, a spin coating method, a printing coating method, a spray coating method, a slot coating method, a roll coating method, a slide coating method, a blade coating method, a gravure coating method, and a wire bar coating method.

The method of the curing treatment is not particularly limited, and examples thereof include a light irradiation treatment and a heating treatment. Among these, from the viewpoint of manufacturing suitability, a light irradiation treatment is preferable, and an ultraviolet irradiation treatment is more preferable.

Irradiation conditions of the light irradiation treatment are not particularly limited, and an irradiation amount of 50 to 1,000 μmJ/cm² is preferable.

In the above description, the method of manufacturing the optical film using the curable composition has been described in detail, but in the present invention, the manufacturing method of the optical film is not limited to the above-described aspect.

For example, in a case of manufacturing the optical film having the region C and the region D, a manufacturing method of the optical film using a composition containing a polymer and a pigment can be mentioned. More specifically, the optical film can be manufactured by applying a composition containing a polymer, a pigment, and a solvent and subjecting the formed coating film to a drying treatment (for example, a heating treatment).

In the preparation of the composition, a process for dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment.

In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

In addition, in a case of manufacturing the optical film having the region F and the region G, a manufacturing method of the optical film using a composition containing a polymer and particles having a predetermined size can be mentioned.

### <Organic EL Display Device>

The above-described optical film according to the embodiment of the present invention is suitably applied to an organic EL display element. In particular, the optical film according to the embodiment of the present invention is suitably applied to an organic EL display element having a microcavity structure.

The organic EL display device according to the embodiment of the present invention preferably includes an organic EL display element having a microcavity structure and the above-described optical film according to the embodiment of the present invention.

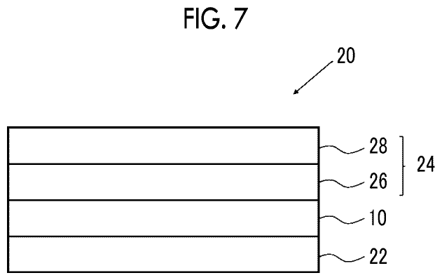

FIG. 7 shows an example of the organic EL display device according to the embodiment of the present invention.

An organic EL display device 20 shown in FIG. 7 includes an organic EL display element 22, an optical film 10, and a circularly polarizing plate 24. The circularly polarizing plate 24 has an optically anisotropic layer 26 and a polarizer 28.

In the present invention, the circularly polarizing plate 24 is any member.

Hereinafter, each configuration will be described in detail.

The optical film 10 is as described above, and thus the description thereof will be omitted.

### (Organic EL Display Element)

The organic EL display element has a microcavity structure.

The microcavity structure is a structure in which only light having a predetermined wavelength is resonated and light having other wavelengths is weakened by matching an optical path length with a peak wavelength of a spectrum of light to be extracted. More specifically, the microcavity structure is a structure in which by matching an optical path length between upper and lower electrodes of an organic EL display element to peak wavelengths of red light, green light, blue light, and the like, which is emitted from the organic EL display element, light is repeatedly reflected between the electrodes, and thus only the light of the peak wavelength is resonated and emphasized, and the light of wavelengths outside the peak wavelength is attenuated (microcavity effect).

The microcavity structure may be a structure capable of obtaining the above effect, and a known structure is adopted.

The organic EL display element is preferably a display element which emits at least blue light, green light, and red light. That is, the organic EL display element preferably has a blue light emitting portion, a green light emitting portion, and a red light emitting portion.

The organic EL display element may be a top emission-type organic EL display element or a bottom emission-type organic EL display element.

### (Circularly Polarizing Plate)

The circularly polarizing plate is an optical element which converts unpolarized light into circularly polarized light. The circularly polarizing plate is disposed on the organic EL display element and contributes to prevention of reflection of external light. The circularly polarizing plate is preferably disposed on a viewing side of the optical film.

The circularly polarizing plate includes an optically anisotropic layer and a polarizer.

The optically anisotropic layer preferably includes a λ/4 plate.

The λ/4 plate is a plate having a λ/4 function, specifically, a plate having a function of converting linearly polarized light having a specific wavelength into circularly polarized light (or converting circularly polarized light into linearly polarized light).

Specific examples of the λ/4 plate include a λ/4 plate described in US2015/0277006A.

Specific examples of the aspect in which the λ/4 plate has a monolayer structure include a stretched polymer film and an optically anisotropic layer formed of a liquid crystal compound.

Specific examples of the aspect in which the λ/4 plate has a multilayer structure include a broadband λ/4 plate formed by laminating a λ/4 plate and a λ/2 plate.

Re(550) of the λ/4 plate is not particularly limited, but from the viewpoint of usefulness as a λ/4 plate, it is preferably 110 to 160 nm and more preferably 120 to 150 nm.

The λ/4 plate preferably exhibits reverse wavelength dispersibility. Exhibition of the reverse wavelength dispersibility of the λ/4 plate means that a retardation (Re) value is equal to or higher as a measurement wavelength is increased in a case where an in-plane Re value at a specific wavelength (visible light range) is measured.

The optically anisotropic layer may include a layer other than the λ/4 plate.

Examples of other layers include a C-plate.

It is sufficient that the polarizer is a member having a function of converting light into specific linearly polarized light (linear polarizer), and an absorption-type polarizer can be mainly used.

Examples of the absorption-type polarizer include an iodine-based polarizer, a dichroic substance-based polarizer using dichroic substances, and a polyene-based polarizer. The iodine-based polarizer and the dichroic substance-based polarizer include a coating type polarizer and a stretching type polarizer, and any one of these polarizers can be applied. However, a polarizer which is produced by allowing polyvinyl alcohol to adsorb iodine or a dichroic substance and performing stretching is preferable.

A relationship between the absorption axis of the polarizer and the in-plane slow axis of the λ/4 plate is not particularly limited, and from the viewpoint that the laminate of the polarizer and the λ/4 plate suitably acts as the circularly polarizing plate, an angle between the absorption axis of the polarizer and the in-plane slow axis of the λ/4 plate is preferably 45°±10°.

### (Other Members)

The organic EL display device may include a member other than the above-described members.

Examples of other members include an adhesive layer. By disposing the adhesive layer between the respective members, adhesiveness between the respective members can be improved.

For example, the adhesive layer may be disposed between the organic EL display element and the optical film. In addition, the adhesive layer may be disposed between the optical film and the circularly polarizing plate. In addition, the adhesive layer may be disposed between the optically anisotropic layer and the polarizer in the circularly polarizing plate.

A material constituting the adhesive layer is not particularly limited, and examples thereof include known materials.

An average refractive index of the adhesive layer at a wavelength of 400 to 700 nm is not particularly limited, but is preferably 1.5 to 1.6.

Examples of the other members include a color filter.

The color filter preferably has a color filter such as a blue color filter, a green color filter, and a red color filter.

In addition, the color filter may have a black matrix having a black color.

### EXAMPLES

Hereinafter, features of the present invention will be described in more detail with reference to Examples and Comparative Examples. The materials, amounts used, proportions, treatment details, and treatment procedure shown in the following Examples can be appropriately changed without departing from the spirit and scope of the present invention. Accordingly, the scope of the present invention should not be construed as being limited by the specific examples given below.

### Example 1

### (Production of Optical Laminate)

A polymerizable liquid crystal composition A having the following formulation was prepared.

Polymerizable liquid crystal composition A

| | | |
|---|---|---|
| Mixture A of rod-like liquid crystal | 100 | parts by mass |
| compounds shown below | | |
| Acrylate monomer (A-400) | 4.2 | parts by mass |
| Polymer A shown below | 2.0 | parts by mass |
| Polymer B shown below | 0.8 | parts by mass |
| Compound A shown below | 1.9 | parts by mass |
| Photopolymerization initiator A shown below | 5.1 | parts by mass |
| Photoacid generator A shown below | 3.0 | parts by mass |
| Methyl isobutyl ketone | 374 | parts by mass |
| Ethyl propionate | 94 | parts by mass |

Mixture A of rod-like liquid crystal compounds (hereinafter, mixture of compounds)

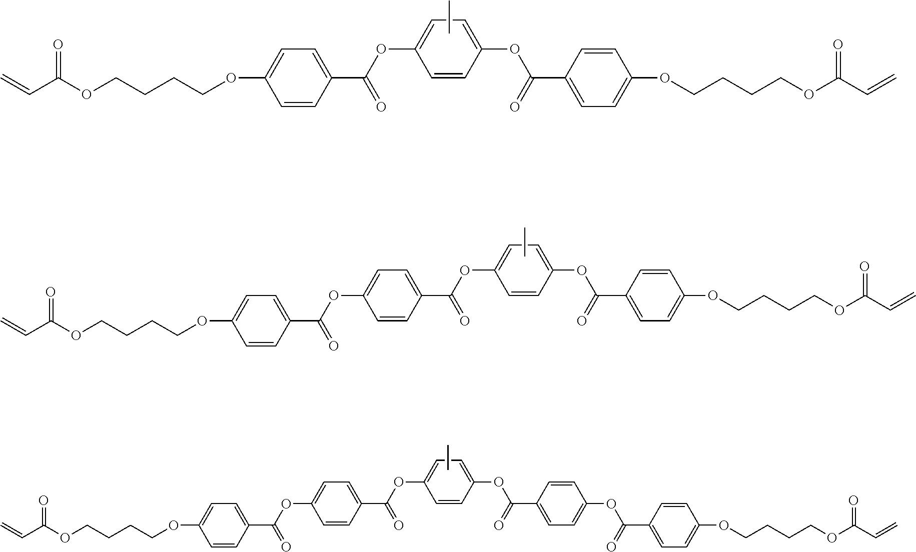

Acrylate monomer (A-400): A-400 (Shin-Nakamura Chemical Co., Ltd.)

Polymer A (the numerical value in the following formulae indicates the content (% by mass) of each repeating unit with respect to all repeating units in the polymer; the weight-average molecular weight is 58,000)

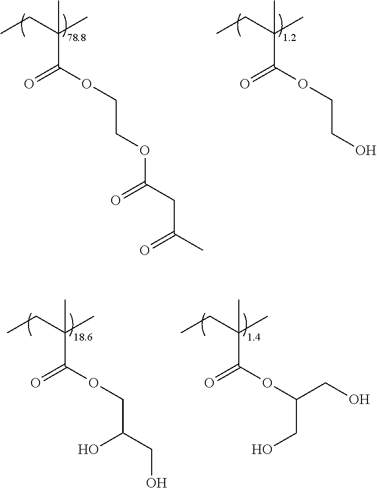

Polymer B (in the following formula, a to e are a:b:c=17:64:19, and indicate the content of each repeating unit with respect to all repeating units in the polymer; the weight-average molecular weight is 70,000)

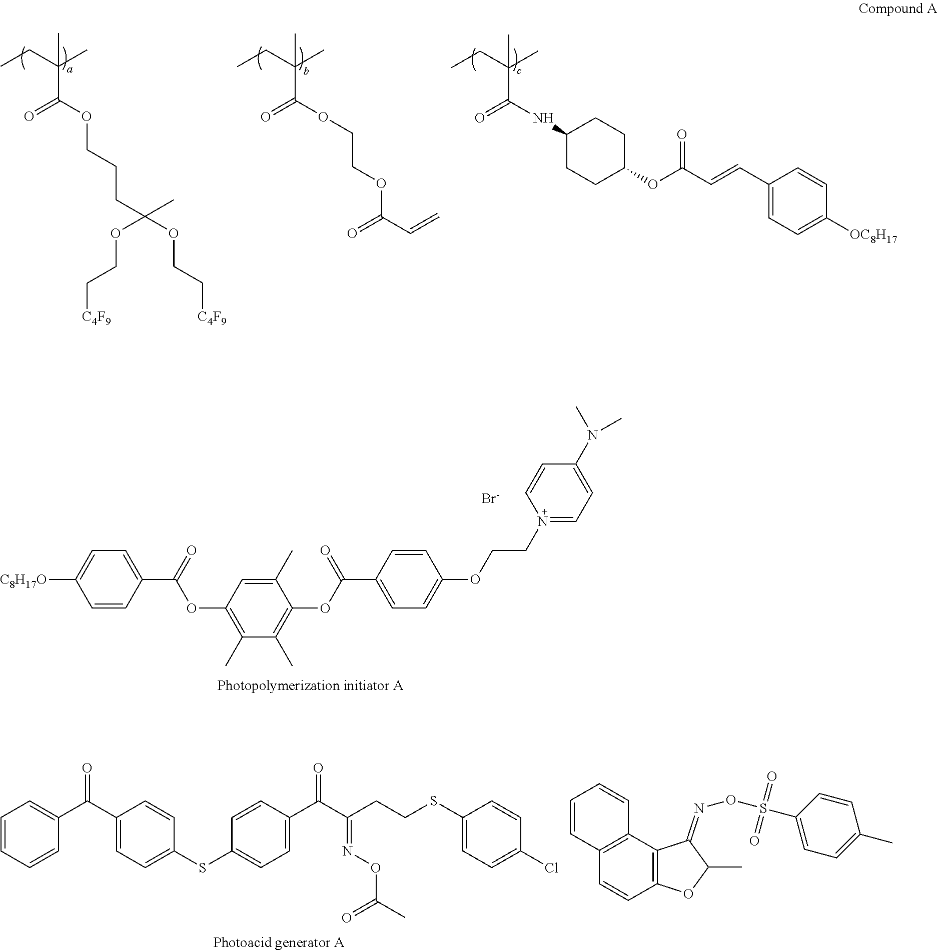

The prepared polymerizable liquid crystal composition A was applied onto a cellulose-based polymer film (TG40, manufactured by FUJIFILM Corporation) as a substrate with a #3.0 wire bar, heated at 70° C. for 2 μminutes, and irradiated with ultraviolet rays of 150 mJ/cm² under a condition of an oxygen concentration of less than 100 ppm by volume. Thereafter, the film was annealed at 120° C. for 1 μminute and irradiated with UV light (ultra-high pressure mercury lamp; UL750, manufactured by HOYA Corporation) at 7.9 mJ/cm² (wavelength: 313 nm) through a wire grid polarizer at room temperature to impart an alignment function, thereby forming an optically anisotropic layer A having a thickness of 0.7 μm. The optically anisotropic layer A was a positive C-plate. A thickness direction retardation Rth(550) of the optically anisotropic layer A was −70 nm.

A polymerizable liquid crystal composition B having the following formulation was prepared.

Polymerizable liquid crystal composition B

| | | |
|---|---|---|
| Rod-like liquid crystal compound B shown below | 21.2 | parts by mass |
| Rod-like liquid crystal compound C shown below | 16.1 | parts by mass |
| Rod-like liquid crystal compound D shown below | 39.0 | parts by mass |
| Rod-like liquid crystal compound E shown below | 8.5 | parts by mass |
| Compound B shown below | 15.3 | parts by mass |
| Photopolymerization initiator A shown above | 0.5 | parts by mass |
| Leveling agent A shown below | 0.09 | parts by mass |
| Cyclopentanone | 173 | parts by mass |
| Methyl ethyl ketone | 52 | parts by mass |
| Triacetin | 10 | parts by mass |

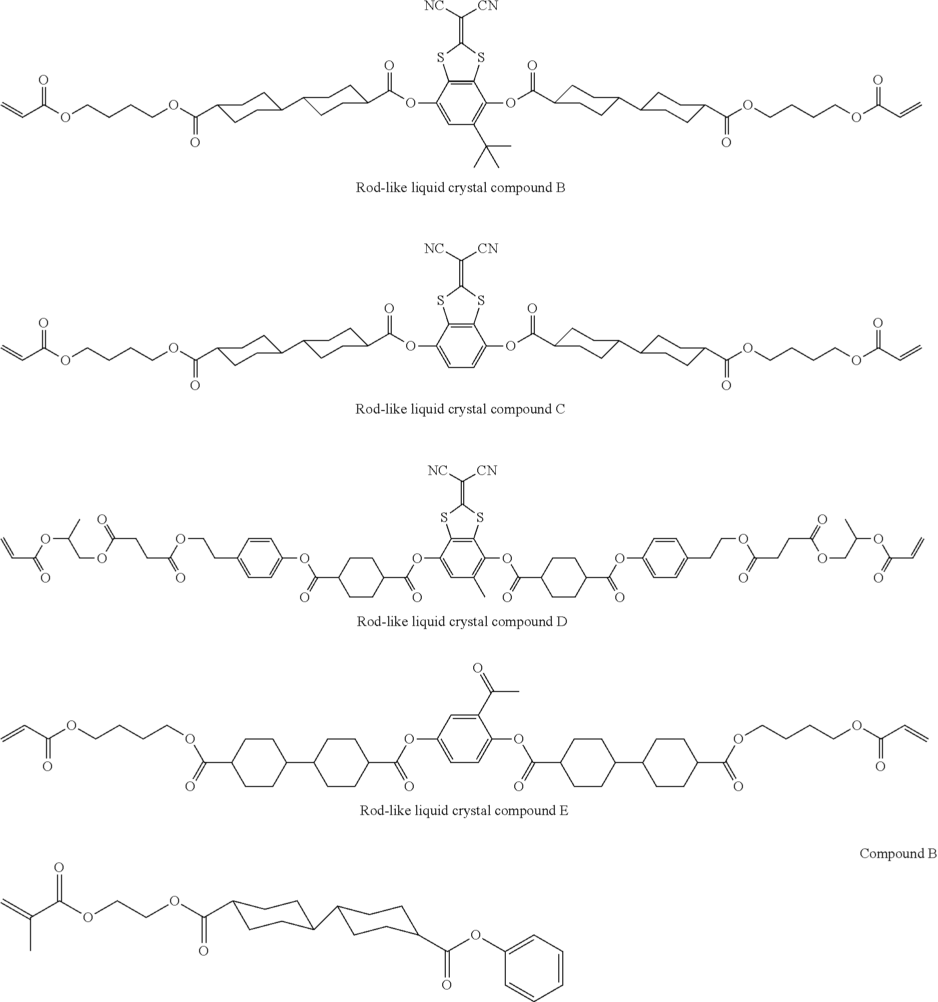

Leveling agent A (the numerical value in the following formulae indicates the content (% by mass) of each repeating unit with respect to all repeating units in the polymer; the weight-average molecular weight is 12,500)

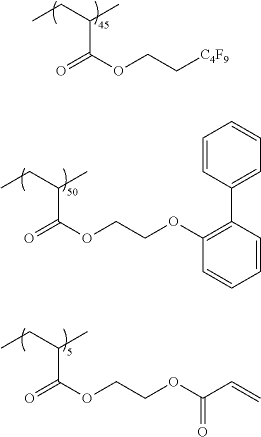

The optically anisotropic layer A formed above was coated with the polymerizable liquid crystal composition B using a wire bar coater #7 to form a composition layer. The formed composition layer was first heated to 120° C. on a hot plate, and the temperature was lowered to 60° C. to stabilize the alignment. Thereafter, using an ultra-high pressure mercury lamp and in a nitrogen atmosphere (oxygen concentration of less than 100 ppm by volume), first ultraviolet irradiation (80 μmJ/cm²) was carried out at a film temperature kept at 60° C., and then second ultraviolet irradiation (300 μmJ/cm²) was carried out at a film temperature kept at 100° C. to fix the alignment to form an optically anisotropic layer B having a thickness of 2.8 m, thereby producing an optical laminate. The optically anisotropic layer B was a positive A-plate. In the optically anisotropic layer B, an in-plane retardation Re(550) at a wavelength of 550 nm was 141 nm, and an angle of an in-plane slow axis with respect to a film width direction was 45°. The above-described angle is an angle represented by a counterclockwise direction as a positive value with respect to a reference (0°) in the film width direction, in a case where the optically anisotropic layer B disposed on the optically anisotropic layer A is observed from the optically anisotropic layer B side.

### (Production of Circularly Polarizing Plate)

A polarizer with a protective film consisting of norbornene-based resin film/polarizer/triacetyl cellulose (TAC) film, in which a hard coat layer was formed on one surface, was produced by a method described in Example 4 of JP2021-015294A. The optical laminate produced above was bonded to the TAC film side of the produced polarizer with a protective film through the adhesive layer B described in Example 4 of JP2021-015294A, such that the optically anisotropic layer B side faced the TAC film side of the polarizer with a protective film and an angle between the absorption axis of the polarizer and the in-plane slow axis of the optically anisotropic layer B was 45°. Thereafter, the cellulose-based polymer film as the substrate was peeled off from the optically anisotropic layer A to produce a circularly polarizing plate.

### (Production of Optical Film A)

A polymerizable composition A having the following formulation was prepared.

Polymerizable composition A

| | | |
|---|---|---|
| Ethylene oxide-modified trimethylolpropane | 100 | parts by mass |
| triacrylate (V#360, manufactured by Osaka | | |
| Organic Chemical Industry Ltd.) | | |
| Photopolymerization initiator A shown above | 3 | parts by mass |
| Leveling agent B shown below | 0.1 | parts by mass |
| Coloring agent A shown below | 10 | parts by mass |
| TECHPOLYMER SSX-102 (manufactured by | 30 | parts by mass |
| Sekisui Kasei Co., Ltd.) | | |
| Cyclohexanone | 143 | parts by mass |

Leveling agent B (the numerical value in the following formulae indicates the content (% by mass) of each repeating unit with respect to all repeating units in the polymer; the weight-average molecular weight is 12,500)

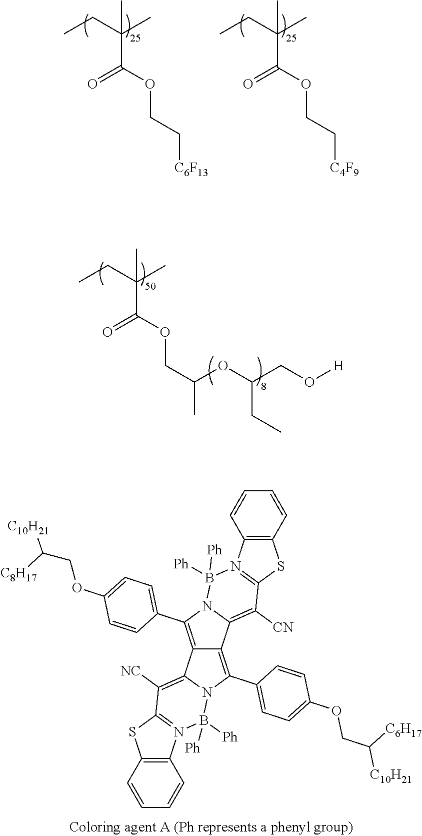

The prepared polymerizable composition A was applied onto a cellulose-based polymer film (Z-TAC, manufactured by FUJIFILM Corporation) as a substrate with a #16 wire bar, heated at 60° C. for 1 μminute, and irradiated with ultraviolet rays of 150 μmJ/cm² under a condition of an oxygen concentration of less than 100 ppm by volume to form, on the substrate, an optical film A having a thickness of 12 μm. An average particle diameter of particles derived from TECHPOLYMER SSX-102 contained in the optical film A was 2 μm.

The optical film A corresponds to the above-described optical film having the region A and the region B.

### (Production of Organic EL Display Device)

A commercially available organic EL display device (Galaxy S4, manufactured by SAMSUNG) (corresponding to an EL display element having a microcavity structure) was disassembled, the bonded polarizer and phase difference film were peeled off, and the optical film A produced above was disposed thereon. In this case, the optical film A and the organic EL display element were bonded to each other using a pressure sensitive adhesive (SK2057, manufactured by Soken Chemical & Engineering Co., Ltd.) such that the cellulose-based polymer film was on the organic EL display element side. Thereafter, the circularly polarizing plate produced above was bonded to the bonded optical film A through the adhesive layer B described in Example 4 of JP2021-015294A, such that the optically anisotropic layer A side was the optical film A side, thereby producing an organic EL display device of Example 1.

### Example 2

An organic EL display device was produced in the same manner as in Example 1, except that the optical film A was changed to an optical film B produced by the following method.

### (Production of Optical Film B)

A polymerizable composition B having the following formulation was prepared.

Polymerizable composition B

| | | |
|---|---|---|
| Ethylene oxide-modified trimethylolpropane | 100 | parts by mass |
| triacrylate (V#360, manufactured by Osaka | | |
| Organic Chemical Industry Ltd.) | | |
| Photopolymerization initiator A shown above | 3 | parts by mass |
| Leveling agent B shown above | 0.1 | parts by mass |
| Coloring agent A shown above | 10 | parts by mass |
| TECHPOLYMER SSX-110 (manufactured by | | |
| Sekisui Kasei Co., Ltd.) | 30 | parts by mass |
| Cyclohexanone | 143 | parts by mass |

The prepared polymerizable composition B was applied onto a cellulose-based polymer film (Z-TAC, manufactured by FUJIFILM Corporation) as a substrate with a #16 wire bar, heated at 60° C. for 1 μminute, and irradiated with ultraviolet rays of 150 μmJ/cm² under a condition of an oxygen concentration of less than 100 ppm by volume to form, on the substrate, an optical film B having a thickness of 12 μm. An average particle diameter of particles derived from TECHPOLYMER SSX-110 contained in the optical film B was 10 μm. The optical film B corresponds to the above-described optical film having the region A and the region B.

### Example 3

An organic EL display device was produced in the same manner as in Example 1, except that the optical film A was changed to an optical film C produced by the following method.

### (Production of Optical Film C)

A composition C having the following formulation was prepared.

Composition C

| | | |
|---|---|---|
| Polymethyl methacrylate | 100 | parts by mass |
| (Mw: 120,000, manufactured | | |
| by Sigma-Aldrich) | | |
| Coloring agent A shown above | 0.5 | parts by mass |
| TECHPOLYMER SSX-102 (manufactured | 5 | parts by mass |
| by Sekisui Kasei Co., Ltd.) | | |
| Tetrahydrofuran | 598 | parts by mass |

The prepared composition C was applied onto a cellulose-based polymer film (Z-TAC, manufactured by FUJIFILM Corporation) as a substrate with a #40 wire bar, and heated at 60° C. for 1 μminute to form, on the substrate, an optical film C having a thickness of 10 μm. An average particle diameter of particles derived from TECHPOLYMER SSX-102 contained in the optical film C was 2 μm.

The optical film C corresponds to the above-described optical film having the region A and the region B.

### Example 4

An organic EL display device was produced in the same manner as in Example 1, except that the optical film A was changed to an optical film D produced by the following method.

### (Production of Optical Film D)

A composition D having the following formulation was prepared.

Composition D

| | |
|---|---|
| Polybenzyl methacrylate | 80 parts by mass |
| (average Mw: to 100,000, | |
| manufactured by Sigma-Aldrich) | |
| Pigment B shown below | 20 parts by mass |
| Propylene glycol monomethyl ether acetate | 525 parts by mass |

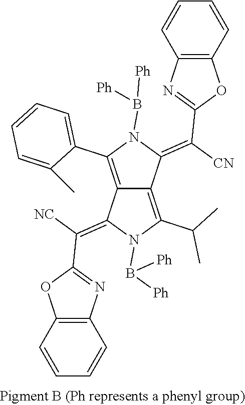 [SMILES: Cc1ccccc1-c1c2/c(=C(\C#N)c3nc4ccccc4o3)n(B(c3ccccc3)c3ccccc3)c(C(C)C)c2/c(=C(\C#N)c2nc3ccccc3o2)n1B(c1ccccc1)c1ccccc1]

In a case of preparing the composition D, a dispersion liquid of the following pigment B was prepared in advance, and the obtained dispersion liquid and each component were mixed to prepare the composition D.

A method of preparing the dispersion liquid of the pigment B is as follows. First, a mixed solution consisting of the pigment B (20 parts by mass) and propylene glycol monomethyl ether acetate (80 parts by mass) was subjected to a dispersion treatment under the following conditions using Ultra Apex Mill manufactured by Kotobuki Sangyo Co., Ltd. as a circulation type dispersion device (beads mill) to produce the dispersion liquid of the pigment B. The dispersion treatment was performed until the pigment had a predetermined size.
Bead diameter: 0.2 μmm
Bead filling rate: 65 vol %
Circumferential speed: 6 μm/sec
Pump supply rate: 10.8 kg/hr
Cooling water: tap water
Inner volume of circular path of beads mill: 0.15 L
Amount of mixed Solution to be dispersed: 0.65 kg

The prepared composition D was applied onto a cellulose-based polymer film (Z-TAC, manufactured by FUJIFILM Corporation) as a substrate with a #18 wire bar, and heated at 60° C. for 1 μminute to form, on the substrate, an optical film D having a thickness of 6 μm. An average particle diameter of the pigment B contained in the optical film D was 1.5 μm.

The optical film D corresponds to the above-described optical film having the region C and the region D.

### Example 5

An organic EL display device was produced in the same manner as in Example 1, except that the optical film A was changed to an optical film E produced by the following method.

### (Production of Optical Film E)

A composition E having the following formulation was prepared.

Composition E

| | |
|---|---|
| Polybenzyl methacrylate | 80 parts by mass |
| (average Mw: to 100,000, | |
| manufactured by Sigma-Aldrich) | |
| Pigment C shown below | 20 parts by mass |
| Propylene glycol monomethyl ether acetate | 525 parts by mass |

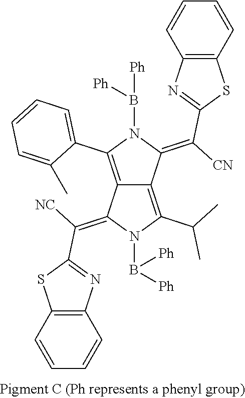 [SMILES: Cc1ccccc1-c1c2/c(=C(\C#N)c3nc4ccccc4s3)n(B(c3ccccc3)c3ccccc3)c(C(C)C)c2/c(=C(\C#N)c2nc3ccccc3s2)n1B(c1ccccc1)c1ccccc1]

In a case of preparing the composition E, a dispersion liquid of the pigment C was prepared in advance, and the obtained dispersion liquid and each component were mixed to prepare the composition E.

A dispersion liquid of the pigment C was prepared according to the same procedure as the method of preparing the dispersion liquid of the pigment B in Example 4 described above, except that the pigment C was used instead of the pigment B and the time of the dispersion treatment was adjusted such that the size of the pigment was a predetermined size.

The prepared composition E was applied onto a cellulose-based polymer film (Z-TAC, manufactured by FUJIFILM Corporation) as a substrate with a #18 wire bar, and heated at 60° C. for 1 μminute to form, on the substrate, an optical film E having a thickness of 6 μm. An average particle diameter of the pigment C contained in the optical film E was 1.5 μm.

The optical film E corresponds to the above-described optical film having the region C and the region D.

### Example 6

An organic EL display device was produced in the same manner as in Example 1, except that the optical film A was changed to an optical film F produced by the following method.

### (Production of Optical Film F)

A composition F having the following formulation was prepared.

Composition F

| | |
|---|---|
| Polybenzyl methacrylate | 80 parts by mass |
| (average Mw: to 100,000, | |
| manufactured by Sigma-Aldrich) | |
| Pigment D shown below | 20 parts by mass |
| Propylene glycol monomethyl ether acetate | 525 parts by mass |

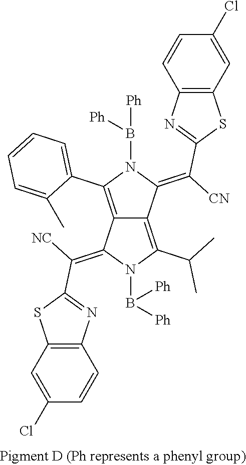 [SMILES: Cc1ccccc1-c1c2/c(=C(\C#N)c3nc4ccc(Cl)cc4s3)n(B(c3ccccc3)c3ccccc3)c(C(C)C)c2/c(=C(\C#N)c2nc3ccc(Cl)cc3s2)n1B(c1ccccc1)c1ccccc1]

In a case of preparing the composition F, a dispersion liquid of the pigment D was prepared in advance, and the obtained dispersion liquid and each component were mixed to prepare the composition F.

A dispersion liquid of the pigment D was prepared according to the same procedure as the method of preparing the dispersion liquid of the pigment B in Example 4 described above, except that the pigment D was used instead of the pigment B and the time of the dispersion treatment was adjusted such that the size of the pigment was a predetermined size.

The prepared composition F was applied onto a cellulose-based polymer film (Z-TAC, manufactured by FUJIFILM Corporation) as a substrate with a #18 wire bar, and heated at 60° C. for 1 μminute to form, on the substrate, an optical film F having a thickness of 6 μm. An average particle diameter of the pigment D contained in the optical film F was 1.5 μm.

The optical film F corresponds to the above-described optical film having the region C and the region D.

### Example 7

An organic EL display device was produced in the same manner as in Example 1, except that the optical film A was changed to an optical film G produced by the following method.

### (Production of Optical Film G)

A composition G having the following formulation was prepared.

Composition G

| | |
|---|---|
| Polybenzyl methacrylate | 80 parts by mass |
| (average Mw: to 100,000, | |
| manufactured by Sigma-Aldrich) | |
| Pigment B shown above | 10 parts by mass |
| TECHPOLYMER SSX-105 | 10 parts by mass |
| (manufactured by Sekisui Kasei Co., Ltd.) | |
| Propylene glycol monomethyl ether acetate | 525 parts by mass |

In a case of preparing the composition G, a dispersion liquid of the pigment B was prepared in advance, and the obtained dispersion liquid and each component were mixed to prepare the composition G.

A dispersion liquid of the pigment B was prepared according to the same procedure as the method of preparing the dispersion liquid of the pigment B in Example 4 described above, except that the time of the dispersion treatment was adjusted such that the size of the pigment was a predetermined size.

The prepared composition G was applied onto a cellulose-based polymer film (Z-TAC, manufactured by FUJIFILM Corporation) as a substrate with a #26 wire bar, and heated at 60° C. for 1 μminute to form, on the substrate, an optical film G having a thickness of 8 μm. An average particle diameter of the pigment B contained in the optical film G was 1.5 μm, and an average particle diameter of the particles derived from TECHPOLYMER SSX-105 was 6 μm.

The optical film G corresponds to the above-described optical film having the region C and the region D.

### Example 8

An organic EL display device was produced in the same manner as in Example 1, except that the optical film A was changed to an optical film H produced by the following method.

### (Production of Optical Film H)

A composition H having the following formulation was prepared.

Composition H

| | |
|---|---|
| Polybenzyl methacrylate | 80 parts by mass |
| (average Mw: to 100,000, | |
| manufactured by Sigma-Aldrich) | |
| Pigment C shown above | 20 parts by mass |
| Propylene glycol monomethyl ether acetate | 525 parts by mass |

In a case of preparing the composition H, a dispersion liquid of the pigment C was prepared in advance, and the obtained dispersion liquid and each component were mixed to prepare the composition H.

A dispersion liquid of the pigment C was prepared according to the same procedure as the method of preparing the dispersion liquid of the pigment B in Example 4 described above, except that the pigment C was used instead of the pigment B and the time of the dispersion treatment was adjusted such that the size of the pigment was a predetermined size.

The prepared composition H was applied onto a cellulose-based polymer film (Z-TAC, manufactured by FUJIFILM Corporation) as a substrate with a #18 wire bar, and heated at 60° C. for 1 μminute to form, on the substrate, an optical film H having a thickness of 6 km. An average particle diameter of the pigment C contained in the optical film H was 100 nm.

The optical film H corresponds to the above-described optical film having the region C and the region D.

### Example 9

An organic EL display device was produced in the same manner as in Example 1, except that the optical film A was changed to an optical film I produced by the following method.

### (Production of Optical Film I)

A composition I having the following formulation was prepared.

Composition I

| | |
|---|---|
| Polybenzyl methacrylate | 96 parts by mass |
| (average Mw: to 100,000, | |
| manufactured by Sigma-Aldrich) | |
| Pigment D shown above | 4 parts by mass |
| Propylene glycol monomethyl ether acetate | 525 parts by mass |

In a case of preparing the composition I, a dispersion liquid of the pigment D was prepared in advance, and the obtained dispersion liquid and each component were mixed to prepare the composition I.

A dispersion liquid of the pigment D was prepared according to the same procedure as the method of preparing the dispersion liquid of the pigment B in Example 4 described above, except that the pigment D was used instead of the pigment B and the time of the dispersion treatment was adjusted such that the size of the pigment was a predetermined size.

The prepared composition I was applied onto a cellulose-based polymer film (Z-TAC, manufactured by FUJIFILM Corporation) as a substrate with a #18 wire bar, and heated at 60° C. for 1 μminute to form, on the substrate, an optical film I having a thickness of 6 μm. An average particle diameter of the pigment D contained in the optical film I was 1.5 μm.

The optical film I corresponds to the above-described optical film having the region C and the region D.

### Example 10

An organic EL display device was produced in the same manner as in Example 1, except that the optical film A was changed to an optical film J produced by the following method.

### (Production of Optical Film J)

A composition J having the following formulation was prepared.

Composition J

| | |
|---|---|
| Polybenzyl methacrylate | 80 parts by mass |
| (average Mw: to 100,000, | |
| manufactured by Sigma-Aldrich) | |
| Pigment E | 20 parts by mass |
| Propylene glycol monomethyl ether acetate | 525 parts by mass |

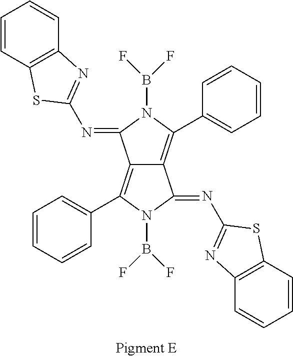 [SMILES: FB(F)N1C(c2ccccc2)=C2C(=C(c3ccccc3)N(B(F)F)/C2=N\c2nc3ccccc3s2)/C1=N/c1nc2ccccc2s1]

In a case of preparing the composition J, a dispersion liquid of the pigment E was prepared in advance, and the obtained dispersion liquid and each component were mixed to prepare the composition J.

A dispersion liquid of the pigment E was prepared according to the same procedure as the method of preparing the dispersion liquid of the pigment B in Example 4 described above, except that the pigment E was used instead of the pigment B and the time of the dispersion treatment was adjusted such that the size of the pigment was a predetermined size.

The prepared composition J was applied onto a cellulose-based polymer film (Z-TAC, manufactured by FUJIFILM Corporation) as a substrate with a #26 wire bar, and heated at 60° C. for 1 μminute to form, on the substrate, an optical film J having a thickness of 7 μm. An average particle diameter of the pigment E contained in the optical film J was 1.0 km.

The optical film J corresponds to the above-described optical film having the region C and the region D.

### Example 11

An organic EL display device was produced in the same manner as in Example 1, except that the optical film A was changed to an optical film K produced by the following method.

### (Production of Optical Film K)

A composition K having the following formulation was prepared.

Composition K

| | |
|---|---|
| Polystyrene | 100 parts by mass |
| (average Mw: 35,000, | |
| manufactured by Sigma-Aldrich Co., LLC) | |
| TECHPOLYMER SSX-105 | 30 parts by mass |
| (manufactured by Sekisui Kasei Co., Ltd. | |
| Propylene glycol monomethyl ether acetate | 525 parts by mass |

The prepared composition K was applied onto a cellulose-based polymer film (Z-TAC, manufactured by FUJIFILM Corporation) as a substrate with a #40 wire bar, and heated at 60° C. for 1 μminute to form, on the substrate, an optical film K having a thickness of 14 km. An average particle diameter of particles derived from TECHPOLYMER SSX-105 contained in the optical film K was 6 km.

The optical film K corresponds to the above-described optical film having the region F and the region G.

### Comparative Example 1

An organic EL display device was produced in the same manner as in Example 1, except that the optical film A was changed to an optical film L produced by the following method.

### (Production of Optical Film L)

A polymerizable composition L having the following formulation was prepared.

Polymerizable composition L

| | | |
|---|---|---|
| Ethylene oxide-modified trimethylolpropane | 100 | parts by mass |
| triacrylate (V#360, manufactured by Osaka | | |
| Organic Chemical Industry Ltd.) | | |
| Photopolymerization initiator A shown above | 3 | parts by mass |
| Leveling agent B shown above | 0.1 | parts by mass |
| Cyclohexanone | 143 | parts by mass |

The prepared polymerizable composition L was applied onto a cellulose-based polymer film (Z-TAC, manufactured by FUJIFILM Corporation) as a substrate with a #16 wire bar, heated at 60° C. for 1 μminute, and irradiated with ultraviolet rays of 150 μmJ/cm² under a condition of an oxygen concentration of less than 100 ppm by volume to form, on the substrate, an optical film L having a thickness of 12 μm.

### <Evaluation>

### (Display Performance (Oblique Tint) of Organic EL Display Device)

Visibility of the organic EL display device produced above was evaluated in a dark room. The organic EL display device was set to display set, and visibility was evaluated according to the following standard by observation from the front surface and at a polar angle of 60°.
A: there was almost no difference in tint between the front surface and the oblique direction, which was particularly excellent.
B: difference in tint was observed in the front surface and the oblique direction, but the difference in tint was small, which was excellent.
C: difference in tint was large between the front surface and the oblique direction, which was unacceptable.

### (Display Performance (Display Glare) of Organic EL Display Device)

Visibility of the organic EL display device produced above was evaluated in a dark room. The organic EL display device was set to display set, and visibility was evaluated according to the following standard by observation from the front surface.
A: display glare was not viewed, which was particularly excellent.
B: display glare was views, which was excellent.
C: display glare was large, which was not acceptable.

As shown in FIG. 2, the optical films used in Examples 1 and 2 had a sea-like region A and an island-like region B. The island-like region B was composed of TECHPOLYMER SSX-102 and TECHPOLYMER SSX-110.

As described above, the optical films used in Examples 3 to 10 had a sea-like region C and an island-like region D.

As described above, the optical film used in Example 11 had a sea-like region F and a island-like region G.

Optical characteristics (λmax, λmin, and scattering rate) of the optical films used in Examples 1 to 11 and in Comparative Example 1 were measured using a goniophotometer (GCMS-3B). In the measurement, the optical characteristics were evaluated using a laminate of the substrate (cellulose-based polymer film) produced above and each optical film. Since the substrate did not affect the optical characteristics (λmax, λmin, and scattering rate), various optical characteristics obtained by the above-described goniophotometer were used as the optical characteristics of each optical film (optical films A to L).

The column of “Scattering rate max” in the table indicates the value of the scattering rate max calculated by the above-described method X.

In the column of “Relationship between λmax and λmin” in the table, “λmax>λmin” indicates that the wavelength λmax was larger than the wavelength λmin, and “λmax<λmin” indicates that the wavelength λmax was smaller than the wavelength λmin.

In the column of “Maximal absorption wavelength≥700 nm” in the table, a case where the maximal absorption wavelength of the coloring agent or pigment used in each of Examples was 700 nm or more is indicated by “A”, and a case where the maximal absorption wavelength was less than 700 nm is indicated by “B”.

In the column of “Requirement 1” of Table 1, a case where the following requirement 1 was satisfied is indicated by “A”, and a case where the requirement 1 was not satisfied is indicated by “B”.

Requirement 1: an average value of scattering rates at respective wavelengths calculated using, as the incidence ray, light at each wavelength in a wavelength range of 580 to 700 nm for each 10 nm is 1.5 times or more an average value of scattering rates at respective wavelengths calculated using, as the incidence ray, light at each wavelength in a wavelength range of 400 to 580 nm for each 10 nm.

In the column of “Requirement 2” of Table 1, a case where the following requirement 2 was satisfied is indicated by “A”, and a case where the requirement 2 was not satisfied is indicated by “B”.

Requirement 2: at any of respective wavelengths in a wavelength range of 400 to 700 nm for each 10 nm, the difference in refractive index between the region A and the region B, the difference in refractive index between the region C and the region D, or the difference in refractive index between the region F and the region G is 0.05 or more, and at any of respective wavelengths in a wavelength range of 400 to 700 nm for each 10 nm, the difference in refractive index between the region A and the region B, the difference in refractive index between the region C and the region D, or the difference in refractive index between the region F and the region G is 0.02 or less.

In the column of “Requirement 3” of Table 1, a case where the following requirement 3 was satisfied is indicated by “A”, and a case where the requirement 3 was not satisfied is indicated by “B”.

Requirement 3: at any of respective wavelengths in a wavelength range of 580 to 700 nm for each 10 nm, the difference in refractive index between the region A and the region B, the difference in refractive index between the region C and the region D, or the difference in refractive index between the region F and the region G is 0.05 or more, and at any of respective wavelengths in a wavelength range of 400 to 580 nm for each 10 nm, the difference in refractive index between the region A and the region B, the difference in refractive index between the region C and the region D, or the difference in refractive index between the region F and the region G is 0.02 or less.

In the column of “Requirement 4” of Table 1, a case where the following requirement 4 was satisfied is indicated by “A”, and a case where the requirement 4 was not satisfied is indicated by “B”.

Requirement 4: at any of respective wavelengths in a wavelength range of 600 to 650 nm for each 10 nm, the difference in refractive index between the region A and the region B, the difference in refractive index between the region C and the region D, or the difference in refractive index between the region F and the region G is 0.05 or more, and at any of respective wavelengths in a wavelength range of 400 to 570 nm for each 10 nm, the difference in refractive index between the region A and the region B, the difference in refractive index between the region C and the region D, or the difference in refractive index between the region F and the region G is 0.02 or less.

In the column of “Relationship between λ1 and λ2” in Table 1, in a case where, among respective wavelengths in A wavelength range of 400 to 700 nm for each 10 nm, a wavelength at which the difference in refractive index between the region A and the region B or the difference in refractive index between the region C and the region D is maximum is defined as a wavelength λ1, and a wavelength at which the difference in refractive index between the region A and the region B or the difference in refractive index between the region C and the region D is minimum is defined as a wavelength λ2, a large/small relation between the wavelength λ1 and the wavelength λ2 is indicated.

TABLE 1

| | | | | | | | | | Maximal | | | | | |
|---|---|---|---|---|---|---|---|---|---|---|---|---|---|---|
| | | | | | Re- | Re- | Re- | Re- | absorption | | | | | |
| | | | | Relationship | quire- | quire- | quire- | quire- | wave- | | | | | |
| | | Optical | Scattering | of λmax and | ment | ment | ment | ment | length ≥700 | | | Relationship | Oblique | Display |
| | | film | rate max | λmin | 1 | 2 | 3 | 4 | nm | λmax | λmin | of Λ1 and λ2 | tint | glare |
| Example | 1 | A | 60% | λmax > λmin | A | A | A | A | A | 700 | 500 | λ1 > λ2 | A | A |
| | | | | | | | | | | nm | nm | | | |
| | 2 | B | 60% | λmax > λmin | A | A | A | A | A | 700 | 500 | λ1 > λ2 | A | B |
| | | | | | | | | | | nm | nm | | | |
| | 3 | C | 10% | λmax > λmin | B | B | B | B | A | 700 | 500 | λ1 > λ2 | B | A |
| | | | | | | | | | | nm | nm | | | |
| | 4 | D | 40% | λmax > λmin | A | A | A | A | A | 700 | 500 | λ1 > λ2 | A | A |
| | | | | | | | | | | nm | rm | | | |
| | 5 | E | 40% | λmax > λmin | A | A | A | A | A | 700 | 495 | λ1 > λ2 | A | A |
| | | | | | | | | | | nm | nm | | | |
| | 6 | F | 40% | λmax > λmin | A | A | A | A | A | 700 | 500 | λ1 > λ2 | A | A |
| | | | | | | | | | | nm | nm | | | |
| | 7 | G | 50% | λmax > λmin | A | A | A | A | A | 620 | 410 | λ1 > λ2 | A | A |
| | | | | | | | | | | nm | nm | | | |
| | 8 | H | 10% | λmax > λmin | A | A | A | A | A | 700 | 495 | λ1 > λ2 | B | A |
| | | | | | | | | | | nm | nm | | | |
| | 9 | I | 15% | λmax > λmin | A | A | A | A | A | 700 | 500 | λ1 > λ2 | B | A |
| | | | | | | | | | | nm | nm | | | |
| | 10 | J | 10% | λmax > λmin | A | A | A | A | B | 670 | 495 | λ1 > λ2 | B | A |
| | | | | | | | | | | nm | nm | | | |
| Comparative | 1 | L | 5% | λmax > λmin | B | B | B | B | — | 400 | 700 | — | C | A |
| Example | | | | | | | | | | nm | rm | | | |

As shown in Table 1, it was found that the optical film according to the embodiment of the present invention exhibited a desired effect.

From the comparison between Example 3 and other examples, it was found that the effect was more excellent in a case where the requirement 1 or the requirement 2 was satisfied.

In addition, from the comparison between Example 5 and Example 8, it was found that the effect was more excellent in a case where the average particle diameter of the pigment was in a range of 0.3 to 5.0 km.

In addition, from the comparison between Example 9 and Examples 4 to 6, it was found that the effect was more excellent in a case where the content of the pigment was 5% to 50% by mass with respect to the total mass of the optical film. The content of the pigment in Example 9 was 4% by mass with respect to the total mass of the optical film.

In addition, from the comparison between Example 10 and Examples 4 to 6, it was found that the effect was more excellent in a case where the maximal absorption wavelength of the pigment was 700 nm or more.

In Example 11, both the evaluation of the oblique tint and the evaluation of the display glare were A. In addition, the scattering rate max was 5000, the relationship of λmax>λmin was satisfied, λmax was 620 nm, and λmin was 410 nm. In Example 11, the above-described above requirement 1 and the following requirement 5 were satisfied.

Requirement 5: the particles constituting the region G are polymer particles, and in any wavelength in the wavelength range of 400 to 700 nm, a difference between a refractive index of a polymer contained in the polymer particles and a refractive index of the polymer contained in the region F is 0.1 or more.

### EXPLANATION OF REFERENCES

10, 10A, 10B: optical film
12: protrusion
20: organic EL display device
22: organic EL display element
24: circularly polarizing plate
26: optically anisotropic layer
28: polarizer

What is claimed is:

1. An optical film,
wherein a wavelength λmax obtained by the following method X is larger than a wavelength λmin obtained by the following method X, and a scattering rate max obtained by the following method X is 10% to 90%, and
wherein an average value of scattering rates at respective wavelengths calculated using, as an incidence ray, light at each wavelength in a wavelength range of 580 to 700 nm for each 10 nm is 1.5 times or more the average value of scattering rates at respective wavelengths calculated using, as the incidence ray, light at each wavelength in a wavelength range of 400 to 580 nm for each 10 nm,
method X: when the incidence ray is incident into the optical film from a normal direction of one surface of the optical film, and a transmittance of light transmitted through the optical film at an angle range of −15° to 15° with respect to a normal direction of the other surface of the optical film is measured for each 1°,
in a case where an integrated value of transmittances in the angle range of −15° to 15° for each 1° is defined as an integrated value A, an integrated value of transmittances in an angle range of −1° to 1° for each 1° is defined as an integrated value B, and a proportion of an absolute value of a difference between the integrated value A and the integrated value B with respect to the integrated value A is defined as a scattering rate,
among scattering rates at respective wavelengths calculated using, as the incidence ray, light at each wavelength in a wavelength range of 400 to 700 nm for each 10 nm, a highest scattering rate is defined as the scattering rate max, a wavelength of the incidence ray at which the scattering rate max is exhibited is defined as the wavelength λmax, and a wavelength of the incidence ray at which a lowest scattering rate is exhibited is defined as the wavelength λmin.

2. The optical film according to claim 1,
wherein the scattering rate max is 40% to 90%.

3. The optical film according to claim 1,
wherein the optical film has a region A and a region B having refractive indices different from each other at any wavelength in the wavelength range of 400 to 700 nm,
a difference in refractive index between the region A and the region B is 0.05 or more at any of respective wavelengths in the wavelength range of 400 to 700 nm for each 10 nm, and
the difference in refractive index between the region A and the region B is 0.02 or less at any of respective wavelengths in the wavelength range of 400 to 700 nm for each 10 nm.

4. The optical film according to claim 3,
wherein, in a case where, among respective wavelengths in the wavelength range of 400 to 700 nm for each 10 nm, a wavelength at which the difference in refractive index between the region A and the region B is maximum is defined as a wavelength λ1, and a wavelength at which the difference in refractive index between the region A and the region B is minimum is defined as a wavelength λ2, the wavelength λ1 is longer than the wavelength λ2.

5. The optical film according to claim 3,
wherein the difference in refractive index between the region A and the region B is 0.05 or more at any of respective wavelengths in a wavelength range of 580 to 700 nm for each 10 nm, and
the difference in refractive index between the region A and the region B is 0.02 or less at any of respective wavelengths in a wavelength range of 400 to 580 nm for each 10 nm.

6. The optical film according to claim 3,
wherein the region A contains a coloring agent.

7. The optical film according to claim 6,
wherein a maximal absorption wavelength of the coloring agent is located at 700 nm or more.

8. The optical film according to claim 6,
wherein the region A contains the coloring agent and a polymer, and
the region B is composed of particles.

9. The optical film according to claim 8,
wherein an average particle diameter of the particles is 5.0 μm or less.

10. The optical film according to claim 1,
wherein the optical film has a region C and a region D having refractive indices different from each other at any wavelength in the wavelength range of 400 to 700 nm,
the region C contains a polymer, and
the region D is composed of a pigment.

11. The optical film according to claim 10,
wherein the scattering rate max is 10% to 50%.

12. The optical film according to claim 11,
wherein the optical film further has a region E which is a region having a refractive index different from the refractive indices of the region C and the region D, and
the region E is composed of particles having an average particle diameter of 4.0 to 9.0 μm.

13. The optical film according to claim 11,
wherein an average particle diameter of the pigment is 0.3 to 5.0 km.

14. The optical film according to claim 11,
wherein a maximal absorption wavelength of the pigment is 700 nm or more.

15. The optical film according to claim 11,
wherein a content of the pigment is 5% to 50% by mass with respect to a total mass of the optical film.

16. The optical film according to claim 1,
wherein the optical film has a region F and a region G having refractive indices different from each other at any wavelength in the wavelength range of 400 to 700 nm,
the region F contains a polymer, and
the region G is composed of particles having an average particle diameter of 4.0 to 9.0 μm.

17. The optical film according to claim 16,
wherein the particles are polymer particles, and
in any wavelength in the wavelength range of 400 to 700 nm, a difference between a refractive index of a polymer contained in the polymer particles and a refractive index of the polymer contained in the region F is 0.1 or more.

18. The optical film according to claim 1,
wherein the optical film is applied to an organic electroluminescent display element having a microcavity structure.

19. An organic electroluminescent display device comprising:
an organic electroluminescent display element having a microcavity structure; and
the optical film according to claim 1.

20. The organic electroluminescent display device according to claim 19, further comprising:
a circularly polarizing plate on a viewing side of the optical film.

21. The organic electroluminescent display device according to claim 19, further comprising:
a color filter on a viewing side of the optical film.

22. The organic electroluminescent display device according to claim 19, further comprising:
an adhesive layer between the organic electroluminescent display element and the optical film.

23. The organic electroluminescent display device according to claim 22,
wherein an average refractive index of the adhesive layer at a wavelength of 400 to 700 nm is 1.5 to 1.6.

24. The organic electroluminescent display device according to claim 19,
wherein the organic electroluminescent display element has a blue light emitting portion, a green light emitting portion, and a red light emitting portion.
